(19) United States
(12) Patent Application Publication
(10) Pub. No.: US 2026/0082672 A1
(43) Pub. Date: Mar. 19, 2026

(54) SEMICONDUCTOR MEMORY DEVICE

(71) Applicant: Kioxia Corporation, Tokyo (JP)

(72) Inventors: Yasunao OTSUKI, Yokkaichi Mie (JP); Kiwamu SAKUMA, Yokkaichi Mie (JP); Kunifumi SUZUKI, Yokkaichi Mie (JP)

(73) Assignee: Kioxia Corporation, Tokyo (JP)

(21) Appl. No.: 19/076,613

(22) Filed: Mar. 11, 2025

(30) Foreign Application Priority Data
Sep. 17, 2024 (JP) 2024-160416

(51) Int. Cl. H10D 64/68; G11C 5/06; H10B 51/10; H10B 51/20

(52) U.S. Cl. CPC H10D 64/689; G11C 5/063; H10B 51/10; H10B 51/20

(57) ABSTRACT

According to one embodiment, in a semiconductor memory device, a third conductive film extends in a third direction intersecting a first direction and a second direction within a first semiconductor film. A fourth conductive film is separated from a third conductive film in the first direction. The fourth conductive film extends in the third direction within the first semiconductor film. A fifth conductive film extends in the third direction within the first semiconductor film between the third conductive film and the fourth conductive film. A reference potential is applied to the fifth conductive film. A first memory cell is provided at a position in which a first conductive film faces the first semiconductor film with a first insulating film interposed therebetween. A second memory cell is provided at a position in which a second conductive film faces the first semiconductor film with a second insulating film interposed therebetween.

### CROSS-REFERENCE TO RELATED APPLICATIONS

This application is based upon and claims the benefit of Japanese Patent Application No. 2024-160416, filed on Sep. 17, 2024; the entire contents of which are incorporated herein by reference.

### FIELD

Embodiments described herein relate generally to a semiconductor memory device.

### BACKGROUND

In a semiconductor memory device including multiple memory cells, the multiple memory cells may be configured to be arranged three-dimensionally. In the semiconductor memory device, in order to highly integrate the multiple memory cells, it is desirable to decrease the size of the memory cells.

### BRIEF DESCRIPTION OF THE DRAWINGS

FIG. 1 is a perspective view illustrating a configuration of a semiconductor memory device according to a first embodiment;

FIG. 2 is a block diagram illustrating the configuration of the semiconductor memory device according to the first embodiment;

FIG. 3 is a circuit diagram illustrating the configuration of the semiconductor memory device according to the first embodiment;

FIG. 4 is a plan view illustrating a configuration of a memory cell array of the first embodiment;

FIG. 5 is a cross-sectional view illustrating the configuration of the memory cell array of the first embodiment;

FIG. 6 is a cross-sectional view illustrating the configuration of the memory cell array of the first embodiment;

FIGS. 7A to 7E are cross-sectional views illustrating a method of manufacturing the semiconductor memory device according to the first embodiment;

FIGS. 8A to 8C are plan views illustrating the method of manufacturing the semiconductor memory device according to the first embodiment;

FIGS. 9A to 9C are plan views illustrating the method of manufacturing the semiconductor memory device according to the first embodiment;

FIG. 10 is a perspective view illustrating a configuration of a semiconductor memory device according to a second embodiment;

FIG. 11 is a circuit diagram illustrating the configuration of the semiconductor memory device according to the second embodiment;

FIG. 12 is a plan view illustrating a configuration of a memory cell array of the second embodiment;

FIG. 13 is a cross-sectional view illustrating the configuration of the memory cell array of the second embodiment;

FIGS. 14A to 14C are plan views illustrating a method of manufacturing the semiconductor memory device according to the second embodiment;

FIG. 15 is a perspective view illustrating a configuration of a semiconductor memory device according to a third embodiment;

FIG. 16 is a circuit diagram illustrating the configuration of the semiconductor memory device according to the third embodiment;

FIG. 17 is a plan view illustrating a configuration of a memory cell of the third embodiment;

FIG. 18 is a plan view illustrating an equivalent circuit of the memory cell of the third embodiment;

FIG. 19 is a plan view illustrating an electron density distribution when the memory cell of the third embodiment is turned on;

FIG. 20 is a diagram illustrating the on/off characteristics of the memory cell of the third embodiment;

FIGS. 21A to 21C are plan views illustrating a method of manufacturing the semiconductor memory device according to the third embodiment; and

FIGS. 22A to 22C are plan views illustrating the method of manufacturing the semiconductor memory device according to the third embodiment.

### DETAILED DESCRIPTION

In general, according to one embodiment, there is provided a semiconductor memory device including a first conductive film, a second conductive film, a first semiconductor film, a first insulating film, a second insulating film, a third conductive film, a fourth conductive film, and a fifth conductive film. The first conductive film extends in a first direction. The second conductive film is separated from the first conductive film in a second direction intersecting the first direction and extends in the first direction. The first semiconductor film is disposed between the first conductive film and the second conductive film and extends in the first direction and the second direction. The first insulating film is disposed between the first conductive film and the first semiconductor film and extends in the first direction. The second insulating film is disposed between the second conductive film and the first semiconductor film and extends in the first direction. The third conductive film extends in a third direction intersecting the first direction and the second direction within the first semiconductor film. The fourth conductive film is separated from the third conductive film in the first direction and extends in the third direction within the first semiconductor film. The fifth conductive film extends in the third direction within the first semiconductor film between the third conductive film and the fourth conductive film and to which a reference potential is applied. A first memory cell is provided at a position in which the first semiconductor film faces the first conductive film with the first insulating film interposed therebetween. A second memory cell is provided at a position in which the first semiconductor film faces the second conductive film with the second insulating film interposed therebetween.

Exemplary embodiments of a semiconductor memory device will be explained below in detail with reference to the accompanying drawings. The present invention is not limited to the following embodiments.

### First Embodiment

A semiconductor memory device according to a first embodiment includes multiple memory cells which are arranged three-dimensionally, and is devised to decrease the size of each memory cell.

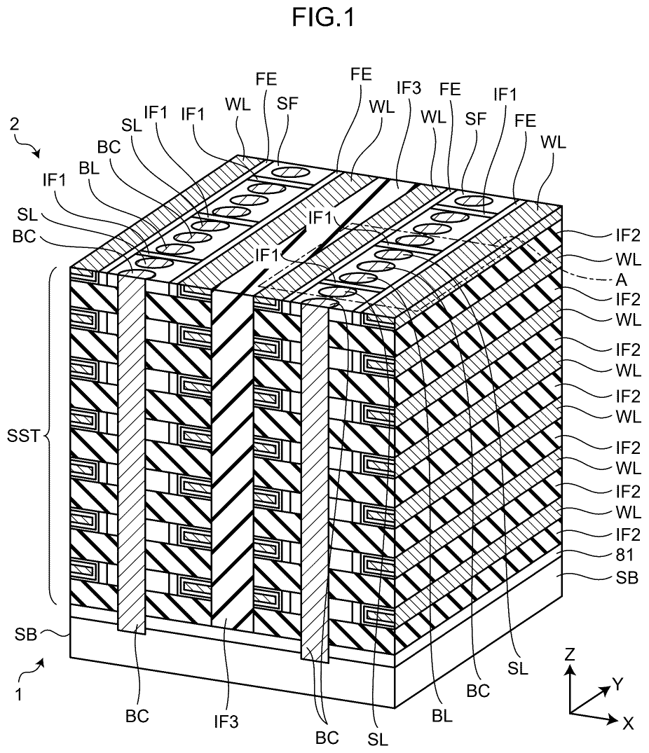

A semiconductor memory device 1 can be configured as illustrated in FIG. 1. FIG. 1 is a perspective view illustrating a configuration of the semiconductor memory device 1.

The semiconductor memory device 1 is a three-dimensional memory, for example, a ferroelectric memory. The semiconductor memory device 1 includes a substrate SB, a memory cell array 2, multiple conductive films (multiple first conductive films, multiple second conductive films) WL, multiple conductive films (multiple third conductive films) BL, multiple conductive films (multiple fifth conductive films) BC, and multiple conductive films (multiple fourth conductive films) SL. Hereinafter, the direction perpendicular to the surface of the substrate SB is defined as the Z direction, and two directions perpendicular to each other in a plane perpendicular to the Z direction are defined as the X direction and the Y direction.

The multiple conductive films WL are stacked on the +Z side of the substrate SB at intervals in the Z direction. An insulating layer IF2 and the conductive film WL may be alternately provided in multiple layers. The multiple conductive films WL are arranged in the X direction. Each conductive film WL extends in a plate shape in the XY directions. Each conductive film WL has a longitudinal direction as the Y direction. For example, the conductive film WL can be formed of a material mainly composed of a metal such as tungsten (W). The substrate SB can be formed of a material mainly composed of a semiconductor such as silicon. The insulating layer IF2 can be formed of an insulator such as silicon oxide.

In the example of FIG. 1, the conductive film WL is divided and insulated in the Y direction by a slit IF3. The slit IF3 can be formed of an insulator such as silicon oxide. The slit IF3 is provided on the +Z side of the substrate SB and extends in the Y direction and the Z direction.

The memory cell array 2 includes multiple semiconductor films SF and multiple insulating films FE.

The multiple semiconductor films SF are stacked on the +Z side of the substrate SB at intervals in the Z direction. The insulating layer IF2 and the semiconductor film SF may be alternately provided in multiple layers. The multiple semiconductor films SF are arranged in the XYZ directions.

The multiple semiconductor films SF which are adjacent to each other in the Y direction between the multiple conductive films WL are electrically isolated by the insulating film IF1. The multiple semiconductor films SF which are adjacent to each other in the X direction with multiple word lines WL interposed therebetween are electrically isolated by the slit IF3. The slit IF3 can be formed of a material mainly composed of an insulator (for example, silicon oxide). The multiple semiconductor films SF which are adjacent to each other in the Z direction are electrically isolated by the insulating layer IF2.

Each semiconductor film SF extends in a plate shape in the XY directions. Each semiconductor film SF can be formed of a semiconductor film mainly composed of a semiconductor (for example, silicon).

The multiple insulating films FE are stacked on the +Z side of the substrate SB at intervals in the Z direction. The insulating layer IF2 and the insulating film FE may be alternately provided in multiple layers. The multiple insulating films FE are arranged in the X direction. Each insulating film FE is disposed between the conductive film WL and the semiconductor film SF in the X direction. Each insulating film FE extends linearly in the Y direction. Each insulating film FE can be formed of an insulator. Each insulating film FE may contain a ferroelectric material.

Each insulating film FE can be formed of a material mainly composed of hafnium oxide (HfO). Each insulating film FE may be formed of a material further containing at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The multiple conductive films BL are arranged in the XY directions on the +Z side of the substrate SB. The arrangement of the multiple conductive films BL in the XY directions corresponds to the arrangement of the multiple semiconductor films SF in the XY directions. Each conductive film BL corresponds to the multiple semiconductor films SF arranged in the Z direction. Each conductive film BL extends in the Z direction through the corresponding semiconductor films SF and reaches the semiconductor film SF closest to the −Z side. Each conductive film BL does not reach the substrate SB. Each conductive film BL extends in the Z direction within the semiconductor film SF. For example, each conductive film BL can be formed of a material mainly composed of a metal such as tungsten (W).

The multiple conductive films SL are arranged in the XY directions on the +Z side of the substrate SB. The arrangement of the multiple conductive films SL in the XY directions corresponds to the arrangement of the multiple semiconductor films SF in the XY directions, and corresponds to the arrangement of the multiple conductive films BL in the XY directions. Each conductive film SL corresponds to the multiple semiconductor films SF arranged in the Z direction. Each conductive film SL extends in the Z direction through the corresponding semiconductor films SF at a position separated from the conductive film BL in the Y direction, and reaches the semiconductor film SF closest to the −Z side. Each conductive film SL does not reach the substrate SB. Each conductive film SL extends in the Z direction within the semiconductor film SF. For example, each conductive film SL can be formed of a material mainly composed of a metal such as tungsten (W).

The multiple conductive films BC are arranged in the XY directions on the +Z side of the substrate SB. The arrangement of the multiple conductive films BC in the XY directions corresponds to the arrangement of the multiple semiconductor films SF in the XY directions, corresponds to the arrangement of the multiple conductive films BL in the XY directions, and corresponds to the arrangement of the multiple conductive films SL in the XY directions. Each conductive film BC corresponds to the multiple semiconductor films SF arranged in the Z direction. Each conductive film BC extends in the Z direction through the corresponding semiconductor films SF at a position between the conductive film BL and the conductive film SL, and reaches the substrate SB. Each conductive film BC extends in the Z direction within the semiconductor film SF. For example, each conductive film BC can be formed of a material mainly composed of a metal such as tungsten (W).

In the semiconductor memory device 1, a stacked body SST is formed by alternately stacking the “conductive film WL, the insulating film FE, and the semiconductor film SF” and the insulating layer IF2. The stacked body SST is disposed on the +Z side of the substrate SB via an interlayer insulating film 81. For example, the interlayer insulating film 81 can be formed of an insulator such as silicon oxide.

In the stacked body SST, the conductive film WL functions as a word line. The conductive film BL functions as a bit line. The conductive film BC functions as a body contact line. The conductive film SL functions as a source line. The semiconductor film SF functions as a channel region. The multiple semiconductor films SF are arranged in the XYZ directions, and each semiconductor film SF is adjacent to the insulating film FE and the conductive film WL in order in the X direction to form a three-dimensional memory cell array. Each of the conductive film BL, the conductive film BC, and the conductive film SL penetrates the stacked body SST.

That is, in the semiconductor memory device 1, a portion of the semiconductor film SF facing the conductive film WL via the insulating film FE is formed to function as a memory cell MT, and the memory cell array 2 in which the multiple memory cells MT are three-dimensionally arranged is configured. In the semiconductor memory device 1, it is possible to increase the storage capacity without using a finer patterning technology by increasing the number of layers of the conductive film WL in the stacked body SST.

Furthermore, selection transistors BT1 and BT2 for selectively supplying a selection potential to the conductive film BL may be provided on the +Z side of the conductive film BL. The selection transistors BT1 and BT2 are respectively driven via selection gate lines SG1 and SG2 connected to their gates. Selection transistors ST1 and ST2 for selectively supplying a selection potential to the conductive film SL may be provided on the +Z side of the conductive film SL. The selection transistors ST1 and ST2 are respectively driven via selection gate lines SG1 and SG2 connected to their gates. For simplification, the selection transistors BT1, BT2, ST1, and ST2 are omitted from FIG. 1.

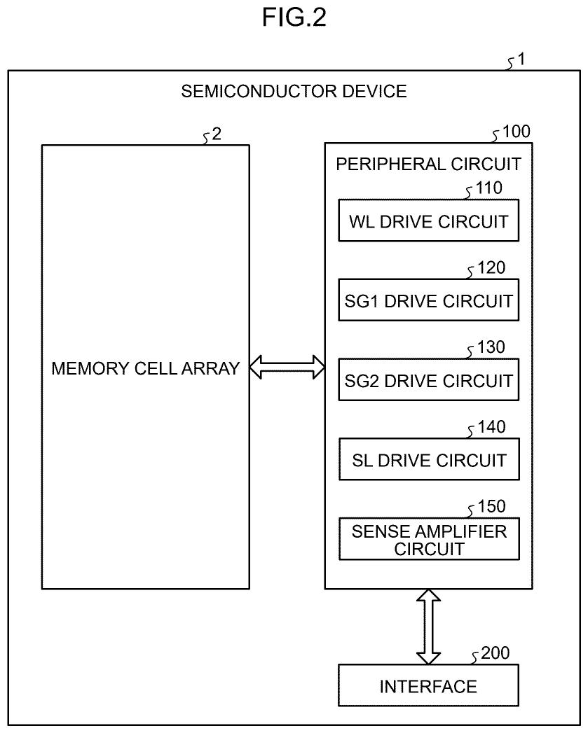

FIG. 2 is a block diagram illustrating a schematic configuration of the semiconductor memory device 1. As illustrated in FIG. 2, the semiconductor memory device 1 includes the memory cell array 2, a peripheral circuit 100, and an interface 200. The peripheral circuit 100 includes a WL drive circuit 110, an SG1 drive circuit 120, an SG2 drive circuit 130, an SL drive circuit 140, and a sense amplifier circuit 150.

The WL drive circuit 110 is a circuit that controls the voltage applied to the conductive film WL, and the SG1 drive circuit 120 is a circuit that controls the voltage applied to the selection gate line SG1. The SG2 drive circuit 130 is a circuit that controls the voltage applied to the selection gate line SG2, and the SL drive circuit 140 is a circuit that controls the voltage applied to the conductive film SL. The sense amplifier circuit 150 is a circuit that controls the voltage applied to the conductive film BL, and is also a circuit that determines the data read out in response to a signal from a selected memory cell.

The peripheral circuit 100 controls the operation of the semiconductor memory device 1 based on instructions input from the outside (for example, a memory controller of a memory system to which the semiconductor memory device 1 is applied) via the interface 200.

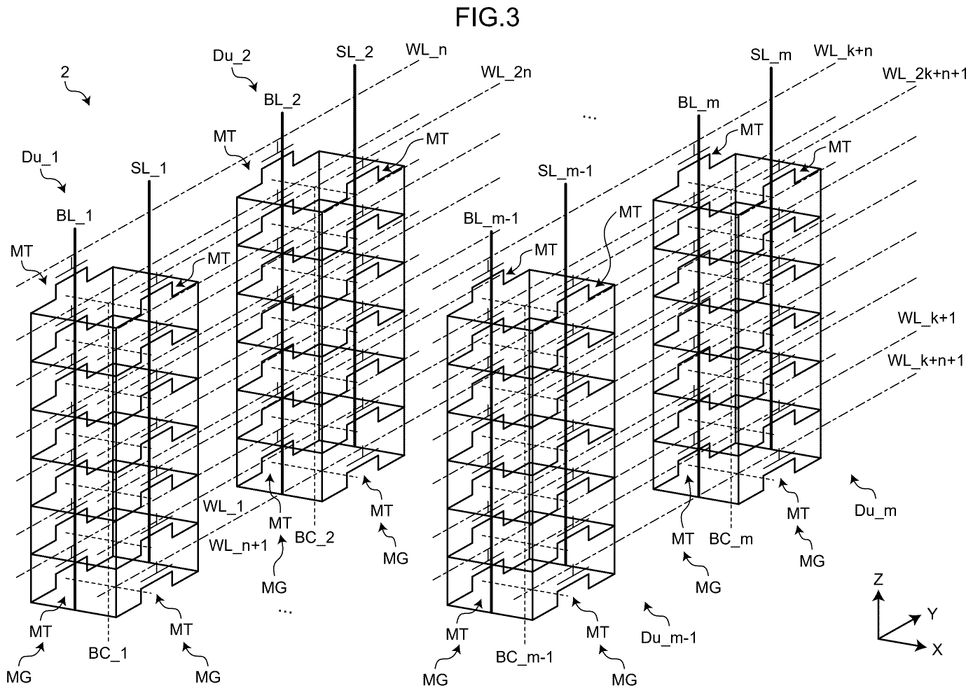

Next, a circuit configuration of the memory cell array 2 will be described with reference to FIG. 3. FIG. 3 is a diagram three-dimensionally illustrating a circuit configuration of the memory cell array 2.

In the memory cell array 2, the multiple memory cells MT are connected in a NOR type circuit. The multiple memory cells MT can be accessed either randomly or serially.

In FIG. 3, the memory cell array 2 is provided with, for example, 2k+n+1 (k and n are each an integer of 2 or more) word lines WL_1 to WL_2k+n+1. Further, the memory cell array 2 is provided with m (m is an integer of 2 or more) bit lines BL_1 to BL_m, m source lines SL_1 to SL_m, and m body contact lines BC_1 to BC_m.

The memory cell array 2 can be divided into m drive units DU_1 to DU_m. Each drive unit DU includes 2n memory cells MT that share the bit line BL, the source line SL, and the body contact line BC. The 2n memory cells MT include two sets of n memory cells MT arranged in the Z direction. The drive units DU are arranged in the XY directions to form a three-dimensional array of the multiple memory cells MT.

In the drive unit DU, n memory cells MT arranged in the Z direction are connected in parallel between the bit line BL and the source line SL to form a NOR type memory cell group MG. Further, two memory cells MT arranged in the X direction are connected in parallel between the bit line BL and the source line SL. That is, each drive unit DU is configured so that two memory cell groups arranged in the X direction share the bit lines BL, source lines SL, and body contact lines BC.

The word lines WL are arranged on both sides of the drive units DU in the X direction and are connected across the drive units DU arranged in the Y direction. The word lines WL are connected to the gates of the multiple memory cells MT arranged in the Y direction.

Furthermore, when the selection transistors BT1 and BT2 are provided on the +Z side of the bit line BL, the drains of the selection transistors BT1 and BT2 are respectively connected to the bit lines BL, and the sources thereof are connected to the global bit lines. The selection transistors BT1 and BT2 are respectively driven via the selection gate lines SG1 and SG2 connected to the gates thereof.

When the selection transistors ST1 and ST2 are provided on the +Z side of the source line SL, the drains of the selection transistors ST1 and ST2 are respectively connected to the source line SL, and the sources thereof are connected to the global source line. The selection transistors ST1 and ST2 are respectively driven via the selection gate lines SG1 and SG2 connected to the gates thereof.

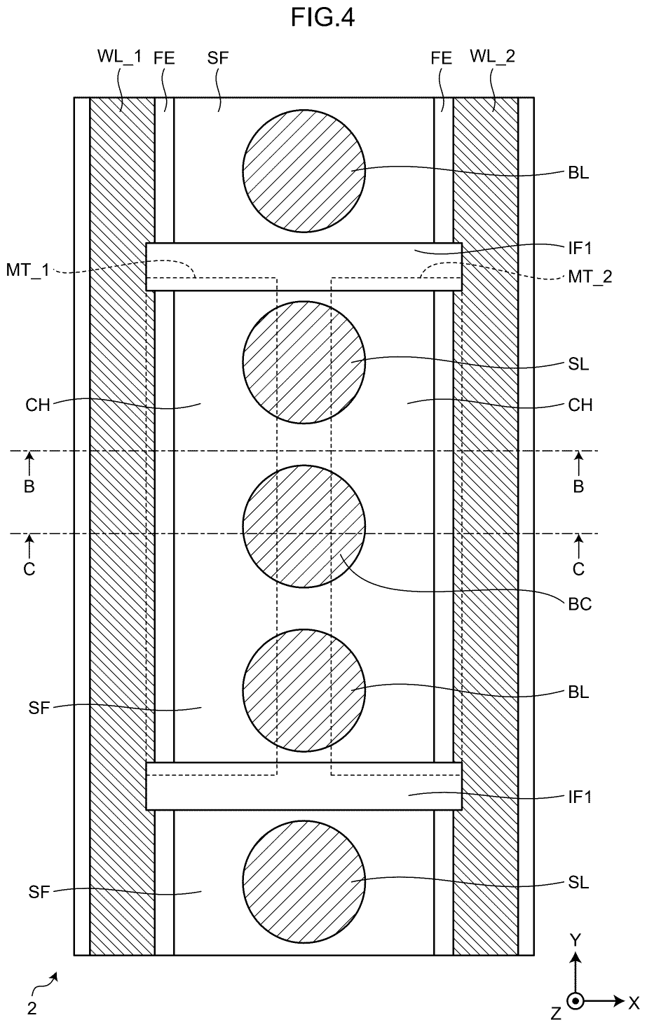

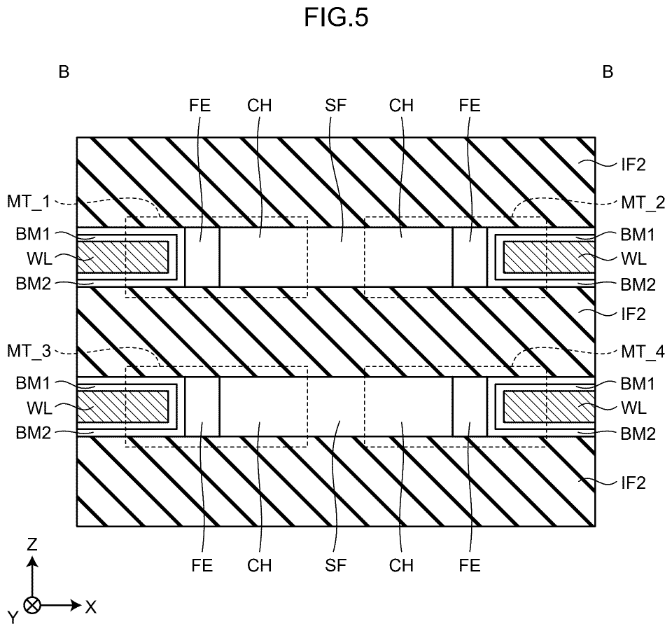

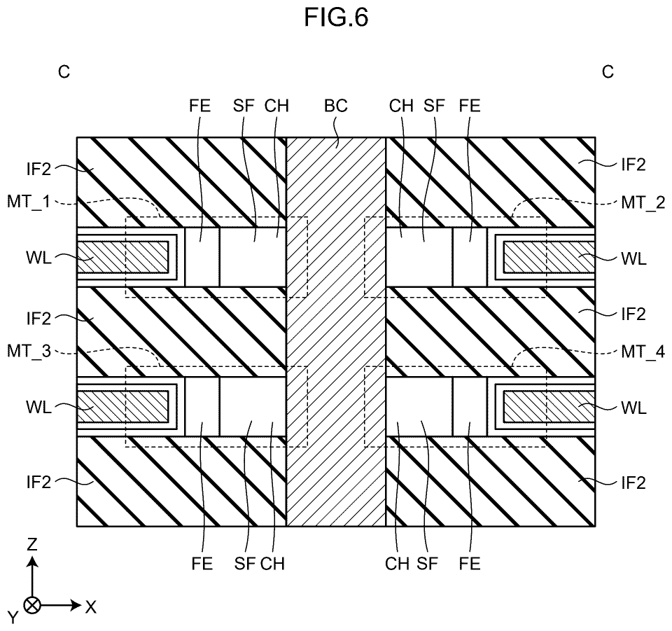

Next, a detailed configuration of the memory cell array 2 will be described with reference to FIGS. 4 to 6. FIG. 4 is an XY plan view illustrating a configuration of the memory cell array 2 and is an enlarged XY plan view corresponding to an A part of FIG. 1. FIG. 5 is an XZ cross-sectional view illustrating a configuration of the memory cell array 2 and illustrates a cross section corresponding to the cross section taken along line B-B of FIG. 4. FIG. 6 is an XZ cross-sectional view illustrating a configuration of the memory cell array 2 and illustrates a cross section corresponding to the cross section taken along line C-C of FIG. 4.

As illustrated in FIG. 4, in the memory cell array 2, the memory cells MT_1 and MT_2 adjacent to each other in the X direction form a back-to-back structure. The memory cells MT_1 and MT_2 adjacent to each other in the X direction share the semiconductor film SF, and share each of the conductive film BL, the conductive film BC, and the conductive film SL. The portion on the −X side of the semiconductor film SF functions as a channel region CH of the memory cell MT_1, and the portion on the +X side of the semiconductor film SF functions as a channel region CH of the memory cell MT_2. The channel region CH of the memory cell MT_1 and the channel region CH of the memory cell MT_2 face each other in the X direction with the conductive film BL, the conductive film BC, and the conductive film SL interposed therebetween. The conductive film BL, the conductive film BC, and the conductive film SL are arranged in the Y direction between the channel region CH of the memory cell MT_1 and the channel region CH of the memory cell MT_2. The conductive film BL, the conductive film BC, and the conductive film SL are separated from each other in the Y direction. The conductive film BC is disposed between the conductive film BL and the conductive film SL in the Y direction.

As illustrated in FIGS. 5 and 6, in the memory cell array 2, the memory cells MT_1 and MT_3 adjacent to each other in the Z direction do not share the semiconductor film SF, but share each of the conductive film BL, the conductive film BC, and the conductive film SL. The channel region CH of the memory cell MT_1 and the channel region CH of the memory cell MT_3 face each other in the Z direction with the insulating layer IF2 interposed therebetween. The channel region CH of the memory cell MT_1 covers the side surfaces of the conductive film BL, the conductive film BC, and the conductive film SL on the −X side. The channel region CH of the memory cell MT_3 covers the side surfaces of the conductive film BL, the conductive film BC, and the conductive film SL on the −X side at the Z position on the −Z side in relation to the channel region CH of the memory cell MT_1.

The memory cells MT_2 and MT 4 adjacent to each other in the Z direction do not share the semiconductor film SF, but share each of the conductive film BL, the conductive film BC, and the conductive film SL. The channel region CH of the memory cell MT_2 and the channel region CH of the memory cell MT 4 are separated from each other in the Z direction with the insulating layer IF2 interposed therebetween. The channel region CH of the memory cell MT_2 covers the side surfaces of the conductive film BL, the conductive film BC, and the conductive film SL on the +X side. The channel region CH of the memory cell MT 4 covers the side surfaces of the conductive film BL, the conductive film BC, and the conductive film SL on the +X side at the Z position on the −Z side in relation to the channel region CH of the memory cell MT_2.

In this structure, the conductive film BL, the conductive film BC, and the conductive film SL respectively function as the bit line, the body contact line, and the source line. A potential corresponding to the operation of the memory cell MT is supplied to the conductive film BL and the conductive film SL.

At this time, since a fixed potential is supplied to the conductive film BC, electric field interference between the memory cells MT_1 and MT_2 adjacent to each other in the X direction can be suppressed. Accordingly, since the channel regions CH can be brought closer to each other while sharing the conductive film BL, the conductive film BC, and the conductive film SL between the memory cells MT_1 and MT_2 adjacent to each other in the X direction, the cell size of each memory cell MT can be decreased.

Further, since a fixed potential is supplied to the conductive film BC, potential fluctuations in the channel region CH can be suppressed. Accordingly, in each memory cell MT, the threshold fluctuation due to the substrate floating effect of the channel region CH can be suppressed, and the influence of noise during reading can be suppressed.

For example, when “1” is written to the selected memory cell MT_1, a selection potential of “1” (for example, −2.5 V) is applied to the conductive film WL of the selected memory cell MT_1, and a non-selection potential (for example, 0 V) is applied to the conductive films WL of the unselected memory cells MT_2 to MT 4. Each of the global bit line and the global source line is controlled to a selection potential of “1” (for example, 2.5 V), and the potential of the substrate SB is controlled to a potential at the time of writing “1” (for example, 2.5 V). The selection potentials of the global bit line and the global source line are respectively supplied to the conductive film BL and the conductive film SL via the selection transistors, and the potential of the substrate SB is supplied to the conductive film BC.

Accordingly, the channel region CH of the selected memory cell MT_1 has a selection potential (for example, 2.5 V), and in the selected memory cell MT_1, an electric field (for example, 5 V) exceeding a threshold value at which the conductive film WL becomes positive with respect to the channel region CH is applied to the insulating film FE, and writing occurs in the memory cell MT to cause a negative shift in Vth. “1” can be written to the memory cell MT. If the memory cell MT is prone to spontaneous polarization, the memory cell can hold “1”. Accordingly, “1” can be properly written to the selected memory cell MT_1.

At this time, since a fixed potential is supplied to the conductive film BC, electric field interference between the memory cells MT_1 and MT_2 adjacent to each other in the X direction can be suppressed, and potential fluctuations in the channel region CH can be suppressed. Since the insulating layer IF2 is interposed between the memory cells MT_1 and MT_3 adjacent to each other in the Z direction, electric field interference can be suppressed. Accordingly, erroneous writing to the unselected memory cells MT_2 to MT 4 can be suppressed.

Alternatively, when “O” is written to the selected memory cell MT_1, a selection potential of “0” (for example, 2.5 V) is applied to the conductive film WL of the selected memory cell MT_1, and a non-selection potential (for example, 0 V) is applied to the conductive films WL of the unselected memory cells MT_2 to MT 4. Each of the global bit line and the global source line is controlled to a selection potential of “0” (for example, −2.5 V), and the potential of the substrate SB is controlled to a potential at the time of writing “0” (for example, −2.5 V). The selection potentials of the global bit line and the global source line are respectively supplied to the conductive film BL and the conductive film SL via the selection transistors, and the potential of the substrate SB is supplied to the conductive film BC.

Accordingly, the channel region CH of the selected memory cell MT_1 has a selection potential (for example, −2.5 V), and in the selected memory cell MT_1, an electric field (for example, −5 V) exceeding a threshold value at which the conductive film WL becomes negative with respect to the channel region CH is applied to the insulating film FE, and writing occurs in the memory cell MT to cause a positive shift in Vth. “O” can be written to the memory cell MT. If the memory cell MT is prone to spontaneous polarization, the memory cell can hold “0”. Accordingly, “0” can be properly written to the selected memory cell MT_1.

At this time, since a fixed potential is supplied to the conductive film BC, electric field interference between the memory cells MT_1 and MT_2 adjacent to each other in the X direction can be suppressed, and potential fluctuations in the channel region CH can be suppressed. Since the insulating layer IF2 is interposed between the memory cells MT_1 and MT_3 adjacent to each other in the Z direction, electric field interference can be suppressed. Accordingly, erroneous writing to the unselected memory cells MT_2 to MT 4 can be suppressed.

Alternatively, when the selected memory cell MT_1 is read, a selection potential at the time of reading (for example, 1.5 V) is applied to the conductive film WL of the selected memory cell MT_1, and a non-selection potential (for example, 0 V) is applied to the conductive films WL of the unselected memory cells MT_2 to MT 4. The global bit line is controlled to a selection potential at the time of reading (for example, 0.5 V), the global source line is controlled to a selection potential at the time of reading (for example, 0 V), and the potential of the substrate SB is controlled to the potential at the time of reading (for example, 0 V). The selection potentials of the global bit line and the global source line are respectively supplied to the conductive film BL and the conductive film SL via the selection transistors, and the potential of the substrate SB is supplied to the conductive film BC.

When “1” is written to the selected memory cell MT_1, a cell current flows from the conductive film BL to the conductive film SL in the channel region CH of the selected memory cell MT_1, and the potential of the conductive film BL decreases. The sense amplifier circuit 150 detects “1” in response to a decrease in potential of the conductive film BL. Accordingly, “1” is read from the selected memory cell MT_1. Alternatively, when “O” is written to the selected memory cell MT_1, a cell current does not flow from the conductive film BL to the conductive film SL in the channel region CH of the selected memory cell MT_1, and the potential of the conductive film BL is maintained. The sense amplifier circuit 150 detects “0” in response to the maintained potential of the conductive film BL. Accordingly, “0” is read from the selected memory cell MT_1.

At this time, since a fixed potential is supplied to the conductive film BC, electric field interference between the memory cells MT_1 and MT_2 adjacent to each other in the X direction can be suppressed. Since the insulating layer IF2 is interposed between the memory cells MT_1 and MT_3 adjacent to each other in the Z direction, electric field interference can be suppressed. Accordingly, erroneous reading of the unselected memory cells MT_2 to MT 4 can be suppressed.

Further, since a fixed potential is supplied to the conductive film BC, potential fluctuations in the channel region CH can be suppressed. Accordingly, the influence of noise on the read signal from the selected memory cell MT_1 can be suppressed.

It should be noted that, as illustrated in FIGS. 5 and 6, a barrier metal may be disposed at the interfaces of the conductive film WL, the insulating layer IF2, and the insulating film FE. The barrier metal may be two layers of barrier metal BM1 and BM2 in this order from the side of the conductive film WL. For example, the barrier metal BM1 can be formed of a material mainly composed of a metal having barrier properties such as titanium. For example, the barrier metal BM2 can be formed of a material mainly composed of a metal nitride having barrier properties such as titanium nitride.

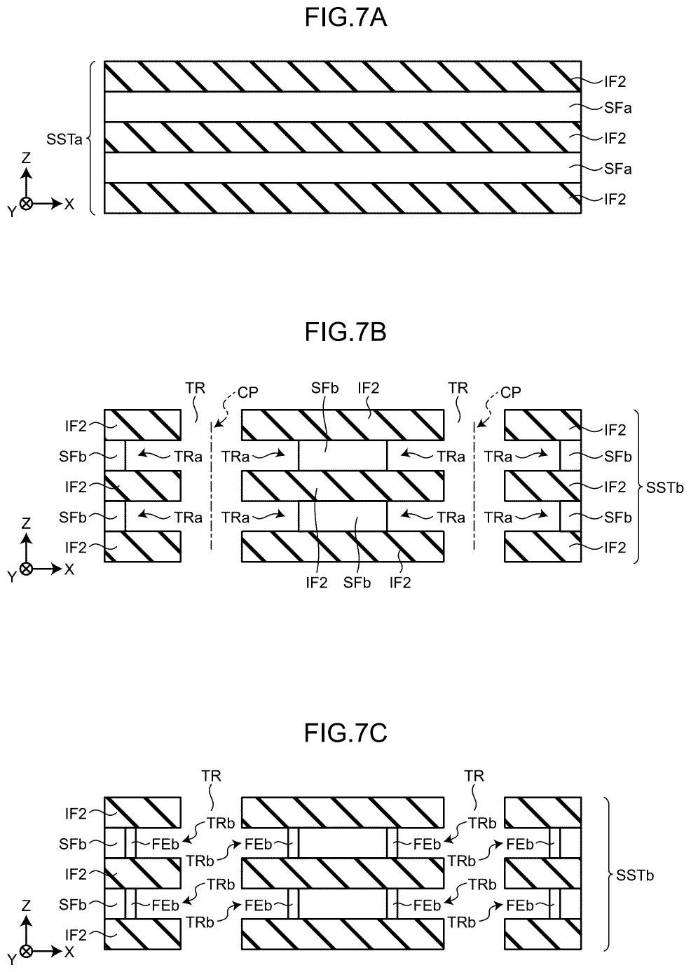

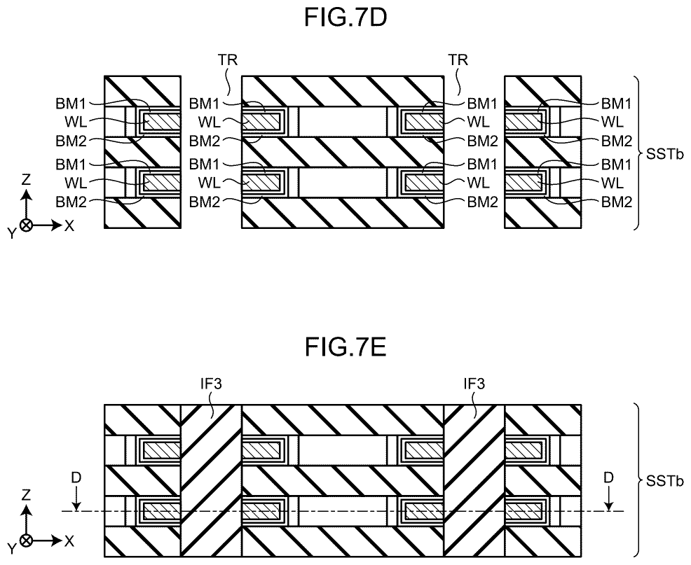

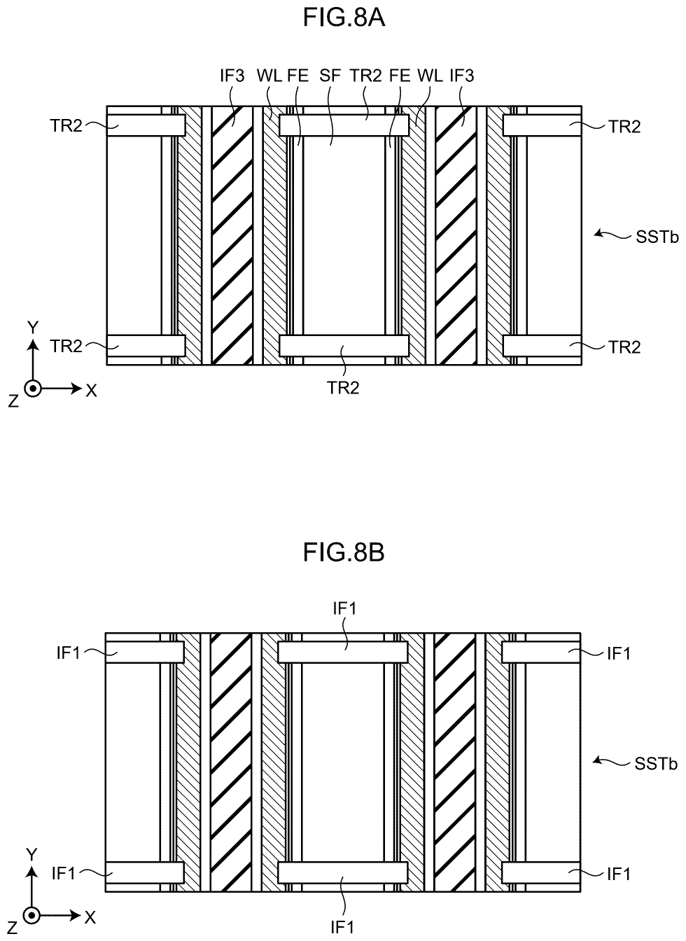

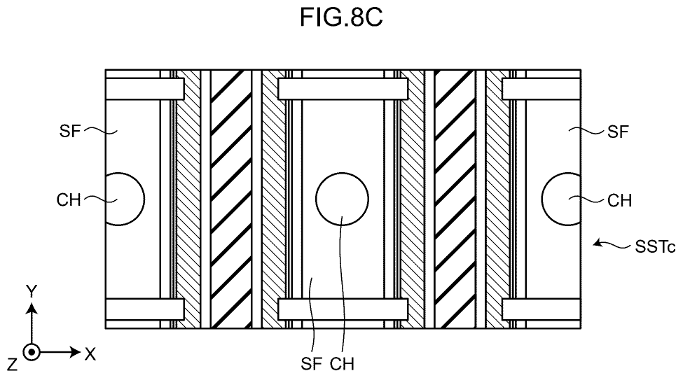

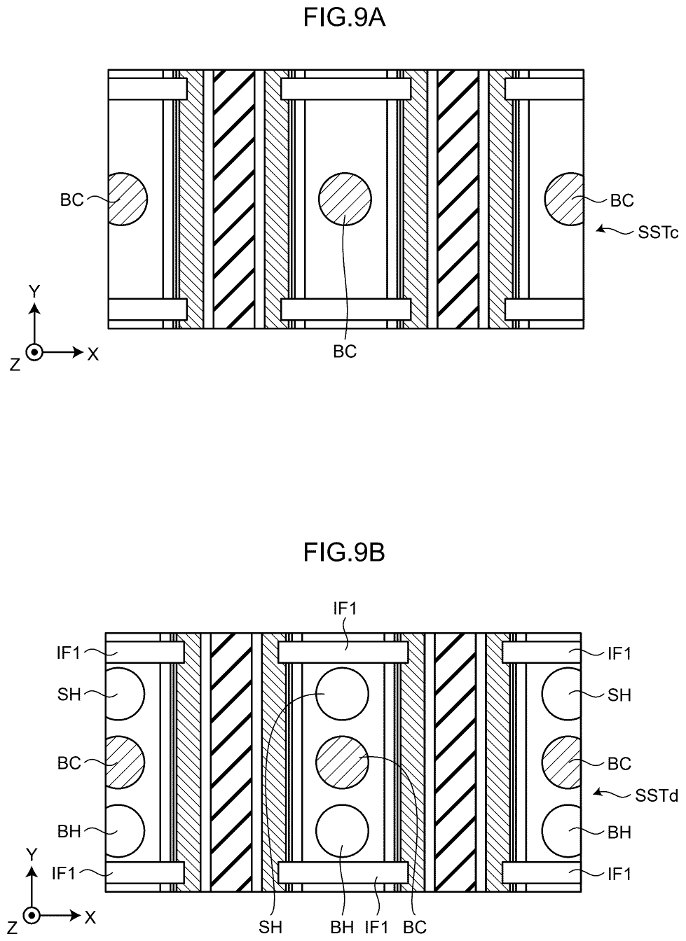

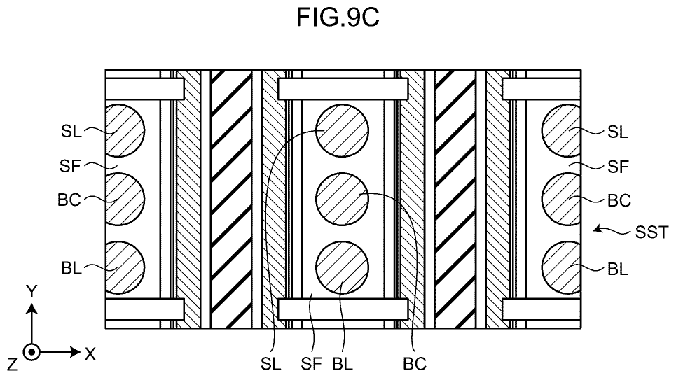

Next, a method of manufacturing the semiconductor memory device 1 will be described with reference to FIGS. 7A to 9C. FIGS. 7A to 7E are cross-sectional views illustrating the method of manufacturing the semiconductor memory device 1. FIGS. 8A to 8C and FIGS. 9A to 9C are plan views illustrating the method of manufacturing the semiconductor memory device 1. FIGS. 8A to 8C and FIGS. 9A to 9C each correspond to an XY cross section taken along line D-D in FIG. 7E.

In the step illustrated in FIG. 7A, a transistor is formed on the substrate SB (see FIG. 1), contact plugs, wiring films, via plugs, and the like are formed on the substrate SB, and the interlayer insulating film 81 is formed around them. Accordingly, the peripheral circuit 100 (see FIG. 2) is formed. Then, an interlayer insulating film is deposited on the +Z side of the substrate SB. The interlayer insulating film 81 (see FIG. 1) can be formed of a material mainly composed of an insulator (for example, a semiconductor oxide such as silicon oxide). The insulating layer IF2 and a semiconductor film SFa are alternately deposited multiple times on the +Z side of the interlayer insulating film 81 to form a stacked body SSTa. The insulating layer IF2 can be formed of a material mainly composed of a semiconductor oxide (for example, silicon oxide). The semiconductor film SFa can be formed of a material mainly composed of a semiconductor (for example, silicon). The film thickness of the insulating layer IF2 and the film thickness of the semiconductor film SFa may be approximately equal or may be different. For example, the film thickness of the insulating layer IF2 may be 30 nm, and the film thickness of the semiconductor film SFa may be 20 nm.

A resist pattern having openings corresponding to the positions for forming the slits IF3 (see FIG. 1) is formed on the uppermost insulating layer IF2 of each stacked body SSTa. Using the resist pattern as a mask, anisotropic etching such as reactive ion etching (RIE) is performed to form a trench TR that extends in the Y direction and penetrates the stacked body SSTa in the Z direction to reach the interlayer insulating film 81.

In the step illustrated in FIG. 7B, a semiconductor film recess process is performed in which the side surface of the semiconductor film SFa exposed by the trench TR is etched and recessed. By the semiconductor film recess process, a recess TRa is formed on the inner surface of the trench TR. The recess TRa is formed at the Z position of the semiconductor film SFa in the stacked body SSTa to be recessed in a direction away from the X-direction center plane CP of the trench TR with respect to the inner surface of the trench TR. For example, the inner surface of the trench TR is wet-etched using an etchant having a high etching selectivity of the semiconductor film SFa to the insulating layer IF2. Alternatively, the inner surface of the trench TR is dry-etched under the condition of isotropic etching using a processing gas having a high etching selectivity of the semiconductor film SFa with respect to the insulating layer IF2. Accordingly, the recess TRa can be formed on the inner surface of the trench TR by etching and recessing a side surface of a semiconductor film SFb exposed by the trench TR. The recess width (recess amount) of the recess TRa with respect to the trench TR can be adjusted by the etching time. The width of the recess TRa in the Z direction is approximately equal to the film thickness of the semiconductor film SFb. The semiconductor film SFb has a stripe shape in the XY plan view.

In the step illustrated in FIG. 7C, an insulating film FEa is deposited on the side surface and the bottom surface of the trench TR. The insulating film FEa is deposited in an amorphous state. At this time, the insulating film FEa is buried in the recess TRa. The insulating film FEa can be formed of a material mainly composed of a ferroelectric material. The insulating film FEa can be formed of an amorphous material.

For example, the insulating film FEa can be formed of a material mainly composed of hafnium oxide (HfO). The insulating film FEa may be formed of a material further containing at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

A resist pattern having openings corresponding to the positions for forming the slit IF3 (see FIG. 1) is formed on the uppermost insulating layer IF2 of each stacked body SSTb. Using the resist pattern as a mask, anisotropic etching such as reactive ion etching (RIE) is performed. Accordingly, the insulating film FEa in the trench TR is removed while remaining the portion buried in the recess TRa of the insulating film FEa.

An insulating film recess process is performed to etch and recess the side surface of the insulating film FEa exposed by the trench TR. A recess TRb is formed on the inner surface of the trench TR by the insulating film recess process. The recess TRb is formed at the Z position of an insulating film FEb in the stacked body SSTb to be recessed in a direction away from the X-direction center plane CP of the trench TR with respect to the inner surface of the trench TR. For example, the inner surface of the trench TR is wet-etched using an etchant having a high etching selectivity of the insulating film FEb with respect to the insulating layer IF2. Alternatively, the inner surface of the trench TR is dry-etched under the condition of isotropic etching using a processing gas having a high etching selectivity of the insulating film FEb with respect to the insulating layer IF2. Accordingly, the recess TRb can be formed on the inner surface of the trench TR by etching and recessing the side surface of the insulating film FEb exposed by the trench TR. The recess width (recess amount) of the recess TRb with respect to the inner surface of the trench TR can be adjusted by the etching time. The width of the recess TRb in the Z direction is approximately equal to the film thickness of the semiconductor film SFb.

The stacked body SSTb is subjected to heat treatment. Accordingly, the insulating film FEb in an amorphous state is crystallized and becomes polycrystalline. At the same time, the crystallinity of the semiconductor film SFb is improved.

In the step illustrated in FIG. 7D, the barrier metal BM2, the barrier metal BM1, and the conductive film WL are buried in the trench TR and the recess TRb in this order. For example, the barrier metal BM2 can be formed of a material mainly composed of a metal nitride having barrier properties such as titanium nitride. For example, the barrier metal BM1 can be formed of a material mainly composed of a metal having barrier properties such as titanium. For example, the conductive film WL can be formed of a material mainly composed of a metal such as tungsten (W).

A resist pattern having openings corresponding to the positions for forming the slit IF3 (see FIG. 1) is formed on the uppermost insulating layer IF2 of each stacked body SSTb. Using the resist pattern as a mask, anisotropic etching such as reactive ion etching (RIE) is performed. Accordingly, the barrier metal BM2, the barrier metal BM1, and the conductive film WL in the trench TR are removed while remaining the portion buried in the recess TRb of each of the barrier metal BM2, the barrier metal BM1, and the conductive film WL.

In the step illustrated in FIG. 7E, the slit IF3 is buried in the trench TR. The slit IF3 can be formed of an insulator such as silicon oxide.

In the step illustrated in FIG. 8A, a resist pattern having openings corresponding to the positions for forming the insulating film IF1 (see FIG. 1) is formed on the uppermost insulating layer IF2 of each stacked body SSTb. Using the resist pattern as a mask, anisotropic etching such as reactive ion etching (RIE) is performed. Accordingly, a trench TR2 is formed at a position, dividing the semiconductor film SFb and the insulating film FEb on both sides in the X direction in the Y direction, to extend in the X direction, penetrate the stacked body SSTb in the Z direction, and reach the interlayer insulating film 81. At this time, the trench TR2 is formed so that the portions of the conductive film WL connected in the Y direction remain on both sides in the X direction. Accordingly, the semiconductor film SFb is divided into multiple semiconductor films SF arranged in the Y direction, and the insulating film FEb is divided into multiple insulating films FE arranged in the Y direction.

In the step illustrated in FIG. 8B, the insulating film IF1 is buried in the trench TR2. The insulating film IF1 can be formed of an insulating material such as silicon oxide.

In the step illustrated in FIG. 8C, a resist pattern having openings corresponding to the positions for forming the conductive film BC (see FIG. 1) is formed on the uppermost insulating layer IF2 of each stacked body SSTb. Using the resist pattern as a mask, anisotropic etching such as reactive ion etching (RIE) is performed. Accordingly, a hole CH is formed in the vicinity of the XY-direction center of the semiconductor film SF to penetrate a stacked body SSTc in the Z direction and reach the substrate SB. At this time, the hole CH is formed so that the portions of the semiconductor film SF connected in the Y direction remain on both sides in the X direction.

In the step illustrated in FIG. 9A, the conductive film BC is buried in the hole CH. For example, the conductive film BC can be formed of a material mainly composed of a metal such as tungsten (W). Accordingly, the conductive film BC is formed to penetrate the semiconductor film SF, extend in the Z direction, and reach the substrate SB.

In the step illustrated in FIG. 9B, a resist pattern having openings corresponding to the positions for forming the conductive films SL and BL (see FIG. 1) is formed on the uppermost insulating layer IF2 of each stacked body SSTc. Using the resist pattern as a mask, anisotropic etching such as reactive ion etching (RIE) is performed. Accordingly, a hole SH is formed between the XY-direction center and the +Y side end of the semiconductor film SF to penetrate a stacked body SSTd in the Z direction and reach the semiconductor film SF closest to the −Z side, and a hole BH is formed between the XY-direction center and the −Y side end of the semiconductor film SF to penetrate the stacked body SSTd in the Z direction and reach the semiconductor film SF closest to the −Z side. At this time, the hole SH is formed so that the semiconductor film SF remains connected in the Y direction on both sides in the X direction and is separated in the Y direction from the insulating film IF1 and the conductive film BC. The hole BH is formed so that the semiconductor film SF remains connected in the Y direction on both sides in the X direction and is separated in the Y direction from the insulating film IF1 and the conductive film BC.

In the step illustrated in FIG. 9C, the conductive film SL is buried in the hole SH, and the conductive film BL is buried in the hole BH. For example, the conductive film SL can be formed of a material mainly composed of a metal such as tungsten (W). For example, the conductive film BL can be formed of a material mainly composed of a metal such as tungsten (W). Accordingly, the conductive film SL is formed to penetrate the semiconductor film SF, extend in the Z direction, and reach the semiconductor film SF closest to the −Z side, and the conductive film BL is formed to penetrate the semiconductor film SF, extend in the Z direction, and reach the semiconductor film SF closest to the −Z side.

In this way, the semiconductor memory device 1 illustrated in FIGS. 1 to 6 can be manufactured by the manufacturing method illustrated in FIGS. 7A to 9C.

As described above, in the first embodiment, in the memory cell array 2 of the semiconductor memory device 1, the memory cells MT adjacent to each other in the X direction form a back-to-back structure in which the semiconductor film SF is shared, and share each of the conductive film BL, the conductive film BC, and the conductive film SL. The conductive film BC is disposed between the conductive film BL and the conductive film SL, extends in the Z direction, and reaches the substrate SB. Accordingly, since a fixed potential can be supplied to the channel region CH via the conductive film BC, the channel regions CH of the memory cells MT_1 and MT_2 adjacent to each other in the X direction can be brought closer to each other while suppressing electric field interference. As a result, in the semiconductor memory device 1, the cell size of each memory cell MT can be decreased.

Further, in the first embodiment, in the semiconductor memory device 1, since a fixed potential can be supplied to the channel region CH of each memory cell MT via the conductive film BC, potential fluctuations in the channel region CH can be suppressed. Accordingly, in each memory cell MT, the threshold fluctuation due to the substrate floating effect of the channel region CH can be suppressed, and the influence of noise during reading can be suppressed.

### Second Embodiment

Next, a semiconductor memory device 101 according to a second embodiment will be described. Hereinafter, the differences from the first embodiment will be mainly described.

Although in the first embodiment, a structure is exemplified in which the conductive film BC as the body contact line is introduced between the memory cells adjacent to each other in the X direction within the memory cell array, in the second embodiment, a structure is exemplified in which an air gap AG is introduced between the memory cells adjacent to each other in the X direction within the memory cell array.

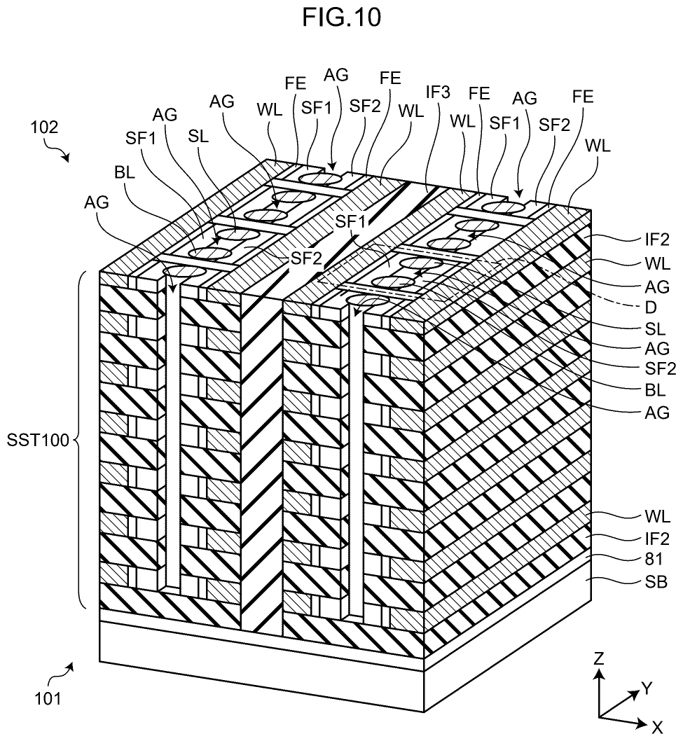

A semiconductor memory device 101 can be configured as illustrated in FIG. 10. FIG. 10 is a perspective view illustrating a configuration of the semiconductor memory device 101.

The semiconductor memory device 101 includes a memory cell array 102 instead of the memory cell array 2 (see FIG. 1) and further includes the air gap AG, and the multiple conductive films BC are omitted.

The memory cell array 102 includes multiple semiconductor films SF1 and multiple semiconductor films SF2 instead of the multiple semiconductor films SF (see FIG. 1). The semiconductor film SF1 and the semiconductor film SF2 can be obtained by dividing the semiconductor film SF in the X direction. The air gap AG is interposed between the semiconductor film SF1 and the semiconductor film SF2 in the X direction. The conductive film SL and the conductive film BL are separated from each other in the Y direction with the air gap AG interposed therebetween. The X width of the air gap AG is smaller than the X width of the conductive film SL, and is smaller than the X width of the conductive film BL.

The difference between the crystal orientation of the semiconductor film SF1 and the crystal orientation of the semiconductor film SF2 is 5° or less. For example, the difference between the orientation of the (100) plane of the semiconductor film SF1 and the orientation of the (100) plane of the semiconductor film SF2 is 5° or less. Accordingly, the semiconductor film SF1 and the semiconductor film SF2 have substantially the same crystal orientation, and can be considered to have crystallinity relatively close to that of a single crystal.

The air gaps AG are arranged in the XY directions on the +Z side of the substrate SB. The arrangement of the multiple air gaps AG in the XY directions correspond to the arrangement of the multiple semiconductor films SF1 in the XY directions, corresponds to the arrangement of the multiple semiconductor films SF2 in the XY directions, corresponds to the arrangement of the multiple conductive films BL in the XY directions, and corresponds to the arrangement of the multiple conductive films SL in the XY directions. Each air gap AG corresponds to the multiple semiconductor films SF1 arranged in the Z direction, and corresponds to the multiple semiconductor films SF2 arranged in the Z direction. Each air gap AG extends in the Z direction between the corresponding semiconductor films SF1 and the corresponding semiconductor films SF2, and reaches the semiconductor film SF closest to the −Z side.

In the semiconductor memory device 101, the portion in which the semiconductor film SF1 or the semiconductor film SF2 faces the conductive film WL with the insulating film FE interposed therebetween functions as the memory cell MT, and the memory cell array 102 in which the multiple memory cells MT are arranged three-dimensionally is configured.

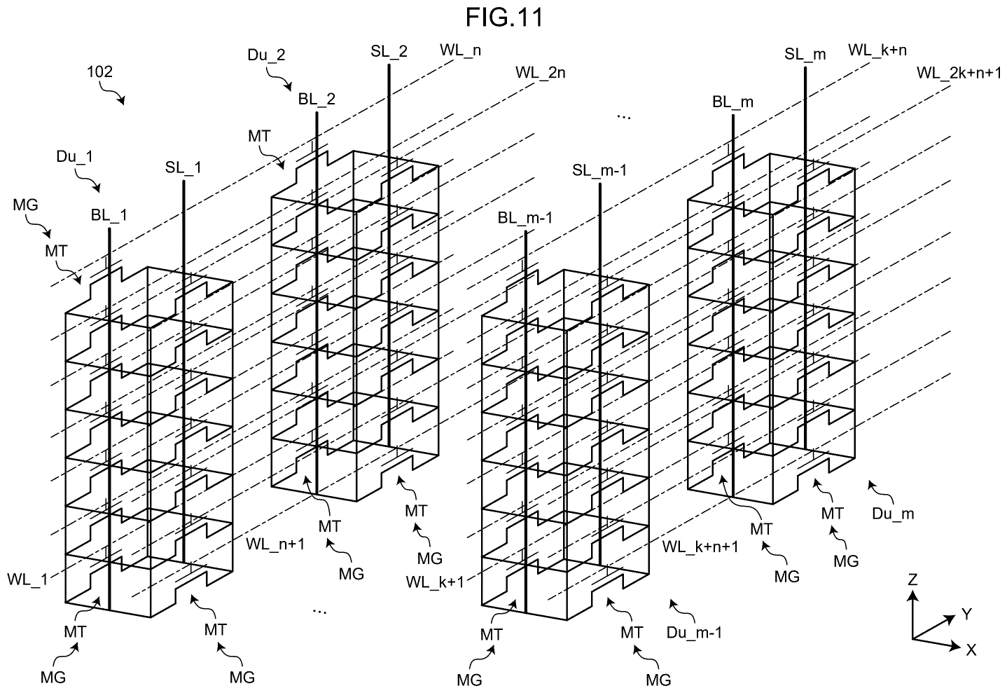

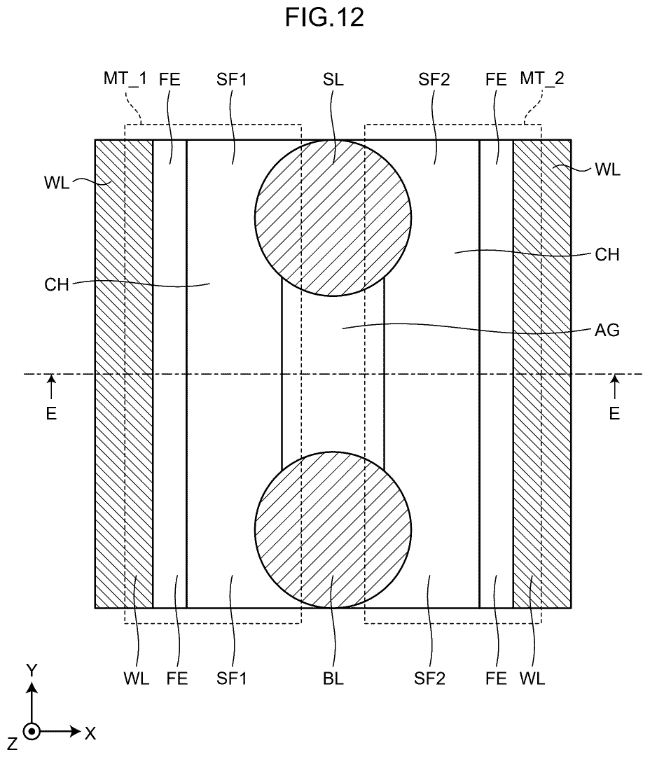

As illustrated in FIG. 11, the circuit configuration of the memory cell array 102 is a configuration in which the body contact lines BC_1 to BC_m are omitted from the circuit configuration of the memory cell array 2 (see FIG. 3). FIG. 11 is a diagram three-dimensionally illustrating the circuit configuration of the memory cell array 102. Each drive unit DU may share the bit line BL and the source line SL in two memory cell groups arranged in the X direction. Except for these points, the circuit configuration of the memory cell array 102 is basically the same as that of the memory cell array 2.

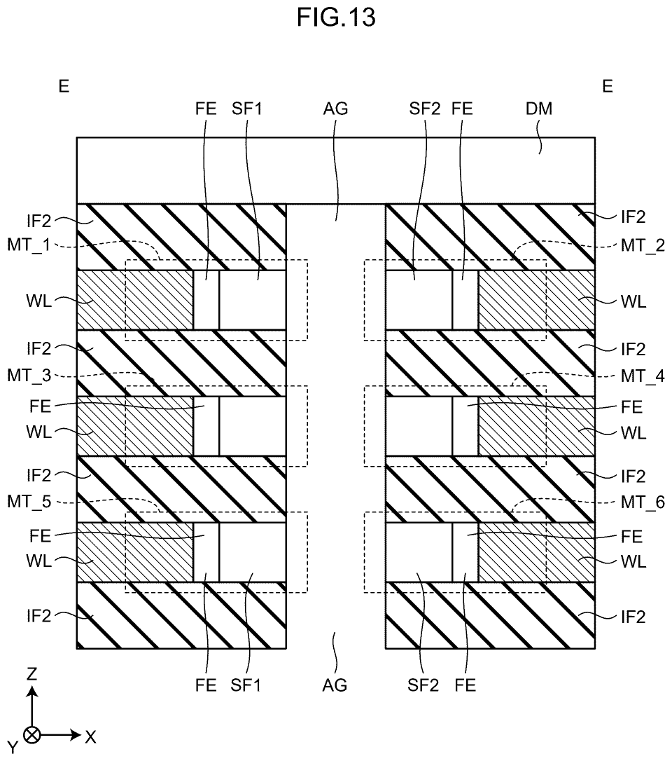

In the memory cell array 102, as illustrated in FIGS. 12 and 13, the air gap AG is introduced between the memory cells MT adjacent to each other in the X direction. FIG. 12 is an XY plan view illustrating a configuration of the memory cell array 102 and is an enlarged XY plan view corresponding to a D part of FIG. 10. FIG. 13 is an XZ cross-sectional view illustrating a configuration of the memory cell array 102 and illustrates a cross section corresponding to the cross section taken along line E-E of FIG. 12.

As illustrated in FIG. 12, in the memory cell array 102, the memory cells MT_1 and MT_2 adjacent to each other in the X direction form the back-to-back structure like the first embodiment, but the memory cells MT_1 and MT_2 of the back-to-back structure are electrically isolated by the air gap AG differently from the first embodiment.

The memory cells MT_1 and MT_2 adjacent to each other in the X direction share each of the conductive film BL and the conductive film SL. The semiconductor film SF1 functions as the channel region CH of the memory cell MT_1, and the semiconductor film SF2 functions as the channel region CH of the memory cell MT_2. The channel region CH of the memory cell MT_1 and the channel region CH of the memory cell MT_2 face each other in the X direction with the conductive film BL, the conductive film SL, and the air gap AG interposed therebetween. The conductive film BL and the conductive film SL are separated from each other in the Y direction with the air gap AG interposed therebetween.

As illustrated in FIGS. 12 and 13, in the memory cell array 102, the memory cells MT_1 and MT_3 adjacent to each other in the Z direction share each of the conductive film BL and the conductive film SL. The channel region CH of the memory cell MT_1 and the channel region CH of the memory cell MT_3 face each other in the Z direction with the insulating layer IF2 interposed therebetween. The channel region CH of the memory cell MT_1 covers the side surfaces of the conductive film BL and the conductive film SL on the −X side. The channel region CH of the memory cell MT_3 covers the side surfaces of the conductive film BL and the conductive film SL on the −X side at the Z position on the −Z side in relation to the channel region CH of the memory cell MT_1.

The memory cells MT_2 and MT 4 adjacent to each other in the Z direction share each of the conductive film BL and the conductive film SL. The channel region CH of the memory cell MT_2 and the channel region CH of the memory cell MT 4 are separated from each other in the Z direction with the insulating layer IF2 interposed therebetween. The channel region CH of the memory cell MT_2 covers the side surfaces of the conductive film BL and the conductive film SL on the +X side. The channel region CH of the memory cell MT 4 covers the side surfaces of the conductive film BL and the conductive film SL on the +X side at the Z position on the −Z side in relation to the channel region CH of the memory cell MT_2.

In this structure, the conductive film BL and the conductive film SL respectively function as the bit line and the source line. A potential corresponding to the operation of the memory cell MT is supplied to the conductive film BL and the conductive film SL.

At this time, since the air gap AG having a smaller dielectric constant than the insulating film is interposed between the channel regions CH of the memory cells MT_1 and MT_2 adjacent in the X direction, parasitic coupling capacitance can be suppressed compared to the case where the insulating film is interposed. Accordingly, electric field interference between the channel regions CH of the memory cells MT_1 and MT_2 adjacent to each other in the X direction can be suppressed. As a result, since the channel regions CH can be brought closer to each other while sharing the conductive film BL and the conductive film SL between the memory cells MT_1 and MT_2 adjacent to each other in the X direction, the cell size of each memory cell MT can be decreased.

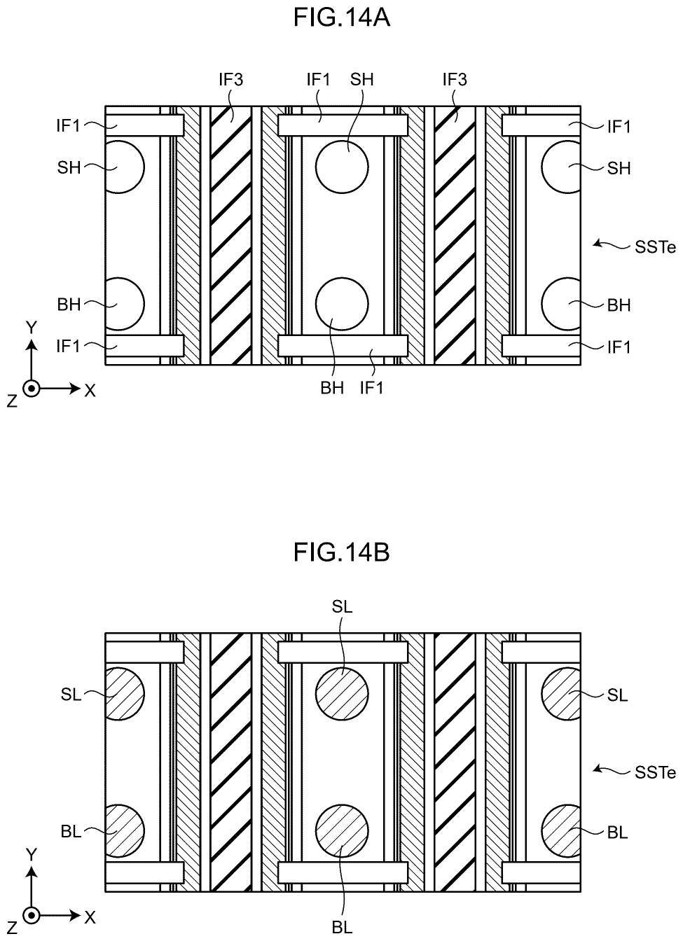

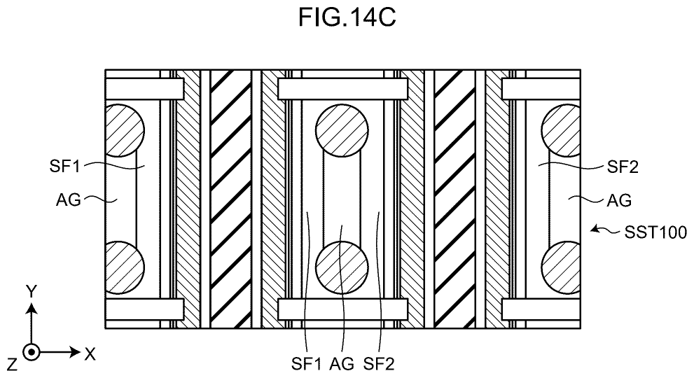

As illustrated in FIGS. 14A to 14C, a method of manufacturing the semiconductor memory device 101 is different from that of the first embodiment in the following points. FIGS. 14A to 14C are plan views illustrating the method of manufacturing the semiconductor memory device 101. FIGS. 14A to 14C each correspond to an XY cross section taken along line D-D in FIG. 7E.

After the steps illustrated in FIGS. 7A to 8B are performed as in the first embodiment, the step illustrated in FIG. 14A is performed.

In the step illustrated in FIG. 14A, a resist pattern having openings corresponding to the positions for forming the conductive films SL and BL (see FIG. 1) is formed on the uppermost insulating layer IF2 of each stacked body SSTb. Using the resist pattern as a mask, anisotropic etching such as reactive ion etching (RIE) is performed. Accordingly, the hole SH is formed between the XY-direction center and the +Y side end of the semiconductor film SF to penetrate a stacked body SSTe in the Z direction and reach the semiconductor film SF closest to the −Z side, and the hole BH is formed between the XY-direction center and the −Y side end of the semiconductor film SF to penetrate the stacked body SSTe in the Z direction and reach the semiconductor film SF closest to the −Z side. At this time, the hole SH is formed so that the semiconductor film SF remains connected in the Y direction on both sides in the X direction and is separated in the Y direction from the insulating film IF1 and the conductive film BC. The hole BH is formed so that the semiconductor film SF remains connected in the Y direction on both sides in the X direction and is separated in the Y direction from the insulating film IF1 and the conductive film BC.

In the step illustrated in FIG. 14B, the conductive film SL is buried in the hole SH, and the conductive film BL is buried in the hole BH. For example, the conductive film SL can be formed of a material mainly composed of a metal such as tungsten (W). For example, the conductive film BL can be formed of a material mainly composed of a metal such as tungsten (W). Accordingly, the conductive film SL is formed to penetrate the semiconductor film SF, extend in the Z direction, and reach the semiconductor film SF on the −Z side, and the conductive film BL is formed to penetrate the semiconductor film SF, extend in the Z direction, and reach the semiconductor film SF closest to the −Z side.

In the step illustrated in FIG. 14C, a resist pattern having openings corresponding to the positions for forming the air gap AG (see FIG. 1) is formed on the uppermost insulating layer IF2 of each stacked body SSTe. Using the resist pattern as a mask, anisotropic etching such as reactive ion etching (RIE) is performed. Accordingly, the air gap AG is formed in the vicinity of the XY-direction center of the semiconductor film SF to penetrate a stacked body SST100 in the Z direction and reach the substrate SB. At this time, in the air gap AG, the semiconductor film SF is divided into two in the X direction to form the semiconductor film SF1 and the semiconductor film SF2. Further, since the air gap AG does not require filling with an insulator, the X width can be easily formed narrow.

As described above, in the second embodiment, in the memory cell array 102 of the semiconductor memory device 101, the memory cells MT adjacent to each other in the X direction form a back-to-back structure to face each other with the air gap AG interposed therebetween and share each of the conductive film BL and the conductive film SL. The air gap AG is disposed between the conductive film BL and the conductive film SL, extends in the Z direction, and reaches the substrate SB. Accordingly, since the air gap AG allows electrical isolation, the channel regions CH of the memory cells MT_1 and MT_2 adjacent to each other in the X direction can be brought closer to each other while suppressing electric field interference. As a result, in the semiconductor memory device 101, the cell size of each memory cell MT can be decreased.

### Third Embodiment

Next, a semiconductor memory device 201 according to a third embodiment will be described. Hereinafter, the differences from the first embodiment and the second embodiment will be mainly described.

In the first embodiment and the second embodiment, a structure between the memory cells adjacent to each other in the X direction within the memory cell array is exemplified, but in the third embodiment, a structure within the memory cell is exemplified.

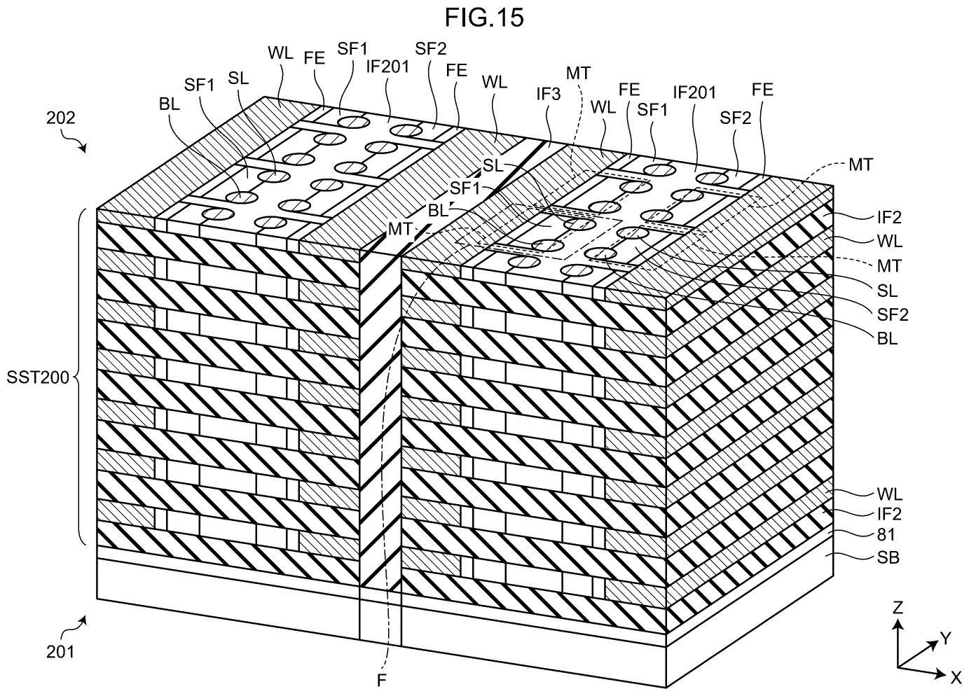

A semiconductor memory device 201 can be configured as illustrated in FIG. 15. FIG. 15 is a perspective view illustrating a configuration of the semiconductor memory device 201.

The semiconductor memory device 201 includes a memory cell array 202 instead of the memory cell array 2 (see FIG. 1), and the conductive film BC is omitted.

The memory cell array 202 includes the multiple semiconductor films SF1 and the multiple semiconductor films SF2 instead of the multiple semiconductor films SF (see FIG. 1). The semiconductor film SF1 and the semiconductor film SF2 can be obtained by dividing the semiconductor film SF in the X direction through an insulating film IF201. The conductive film SL and the conductive film BL are respectively provided with the multiple semiconductor films SF1 and the multiple semiconductor films SF2.

The conductive film SL provided on the semiconductor film SF1 and the conductive film SL provided on the semiconductor film SF2 are separated from each other in the X direction with the insulating film IF2 interposed therebetween. The conductive film BL provided on the semiconductor film SF1 and the conductive film BL provided on the semiconductor film SF2 are separated from each other in the X direction with the insulating film IF2 interposed therebetween.

The conductive film SL and the conductive film BL provided on the semiconductor film SF1 are separated from each other in the Y direction with the insulating film IF2 interposed therebetween. The conductive film SL and the conductive film BL provided on the semiconductor film SF2 are separated from each other in the Y direction with the insulating film IF2 interposed therebetween.

In the semiconductor memory device 201, the portion of the semiconductor film SF1 or the semiconductor film SF2 facing the conductive film WL with the insulating film FE interposed therebetween functions as the memory cell MT, and the memory cell array 202 in which the multiple memory cells MT are arranged three-dimensionally is configured.

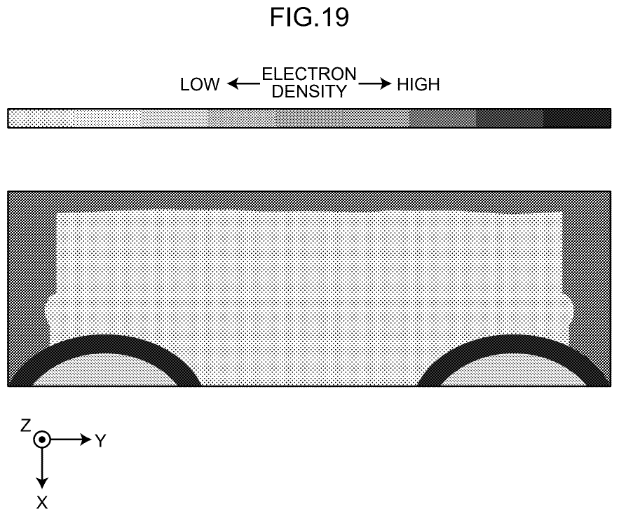

The memory cell array 202 is different from the first and second embodiments in that each memory cell MT is doped with impurities in both end regions in the Y direction in the channel region CH (see FIG. 19). Accordingly, even when the conductive film SL and the conductive film BL are brought closer to each other in each of the semiconductor film SF1 and the semiconductor film SF2, the cell current in the on state can be secured in the regions on both ends of the channel region CH in the Y direction. As a result, the cell size of the memory cell MT can be decreased while suppressing deterioration of the on/off characteristics of the memory cell MT and securing the cell current when the memory cell MT is turned on.

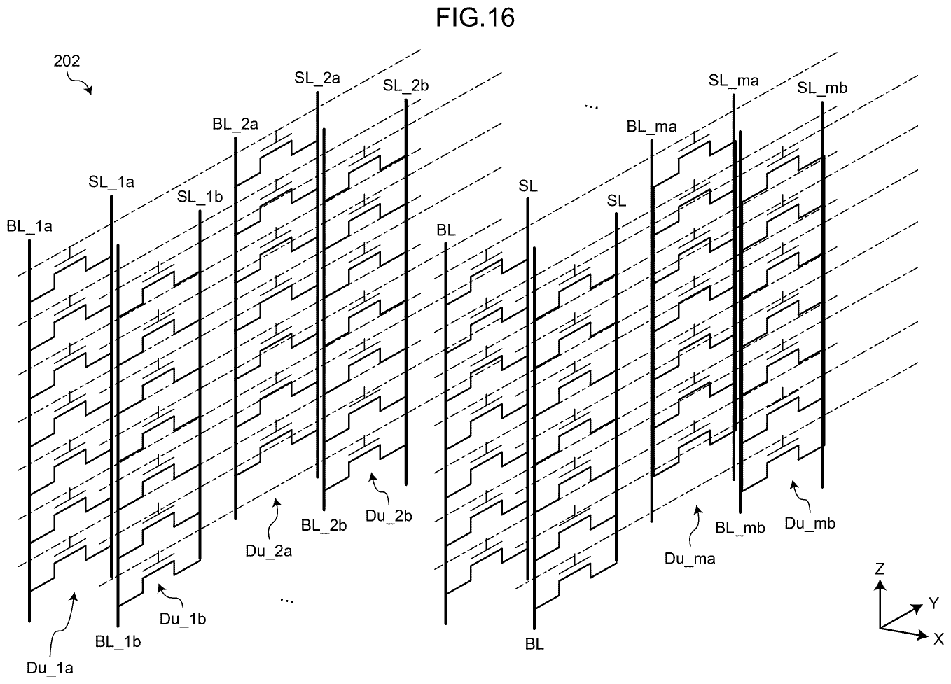

As illustrated in FIG. 16, the circuit configuration of the memory cell array 202 is the same as that of the memory cell array 2 (see FIG. 3) except that the body contact lines BC_1 to BC_m are omitted and the bit lines BL and source lines SL are divided into two in the X direction. FIG. 16 is a diagram three-dimensionally illustrating a circuit configuration of the memory cell array 202.

The bit line BL_1 is divided into two bit lines BL_1a and BL_1b arranged in the X direction. The source line SL_1 is divided into two source lines SL_1a and SL_1b arranged in the X direction. The bit line BL 2 is divided into two bit lines BL 2a and BL 2b arranged in the X direction. The source line SL 2 is divided into two source lines SL 2a and SL 2b arranged in the X direction. The bit line BL_m is divided into two bit lines BL ma and BL mb arranged in the X direction. The source line SL_m is divided into two source lines SL ma and SL mb arranged in the X direction.

As the bit lines BL and the source lines SL are divided into two in the X direction, each drive unit DU is divided into two in the X direction.

The drive unit DU_1 is divided into two drive units DU_1a and DU_1b arranged in the X direction. The drive unit DU 2 is divided into two drive units DU 2a and DU 2b arranged in the X direction. The drive unit DU_m is divided into two drive units DU ma and DU_mb arranged in the X direction.

Except for these points, the circuit configuration of the memory cell array 202 is basically the same as that of the memory cell array 2.

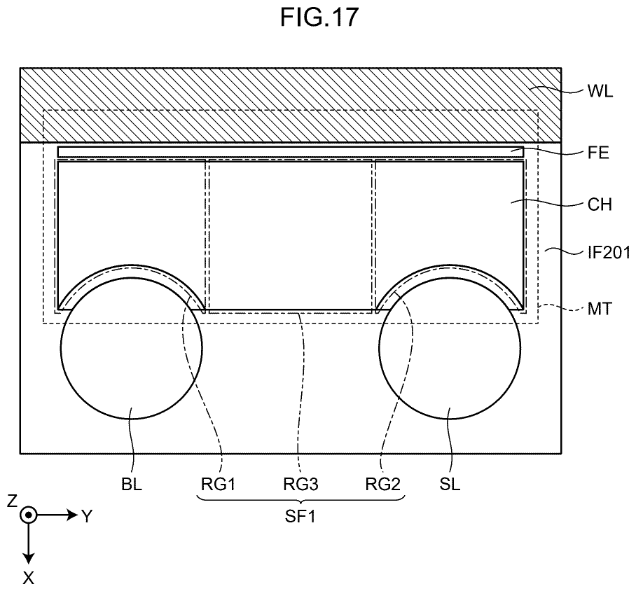

Each memory cell MT can be configured as illustrated in FIG. 17. FIG. 17 is a plan view illustrating a configuration of the memory cell MT. FIG. 17 is an enlarged XY plan view corresponding to the F part in FIG. 15. FIG. 17 illustrates the configuration of the memory cell MT including the semiconductor film SF1, but the configuration of the memory cell MT including the semiconductor film SF2 can be obtained by modifying the configuration of the memory cell MT including the semiconductor film SF1 linearly symmetrically with respect to the Y axis. The other points are the same.

In the memory cell MT illustrated in FIG. 17, the semiconductor film SF1 functioning as the channel region CH includes a region RG1, a region RG2, and a region RG3. The region RG1 is disposed between the conductive film WL and the conductive film BL. The region RG2 is disposed between the conductive film WL and the conductive film SL. The region RG3 is disposed between the region RG1 and the region RG2.

Each of the region RG1 and the region RG2 contains a first conductive type impurity at a concentration C1. The region RG1 may contain the first conductive type impurity at the concentration C1 in the entire region, or may contain the first conductive type impurity at the concentration C1 in the portion on the −Y side. The region RG2 may contain the first conductive type impurity at the concentration C1 in the entire region, or may contain the first conductive type impurity at the concentration C1 in the portion on the +Y side. The concentration C1 can be experimentally determined in advance as an impurity concentration that can realize the cell current required for the memory cell MT in the on state depending on the processing dimensions of the semiconductor film SF1. The concentration C1 may be equal to or larger than 1.0×10¹⁸ cm⁻³. When the first conductive type is N-type, the first conductive type impurity may be an N-type impurity such as phosphorus or arsenic.

The region RG3 contains a second conductive type impurity at a concentration C2. The region RG3 may contain the second conductive type impurity at the concentration C2 in the entire region or may contain the second conductive type impurity at the concentration C2 in the portion on the +X side. The concentration C2 is lower than the concentration C1. The concentration C2 can be experimentally determined in advance as an impurity concentration that can keep the leakage between the conductive film BL and the conductive film SL within an allowable range depending on the processing dimensions of the semiconductor film SF1. The concentration C2 may be equal to or larger than 5.0×10¹⁷ cm⁻³ and smaller than 1.0×10¹⁸ cm⁻³. The second conductive type is the opposite conductive type of the first conductive type. When the second conductive type is P-type, the second conductive type impurity may be a P-type impurity such as boron or aluminum.

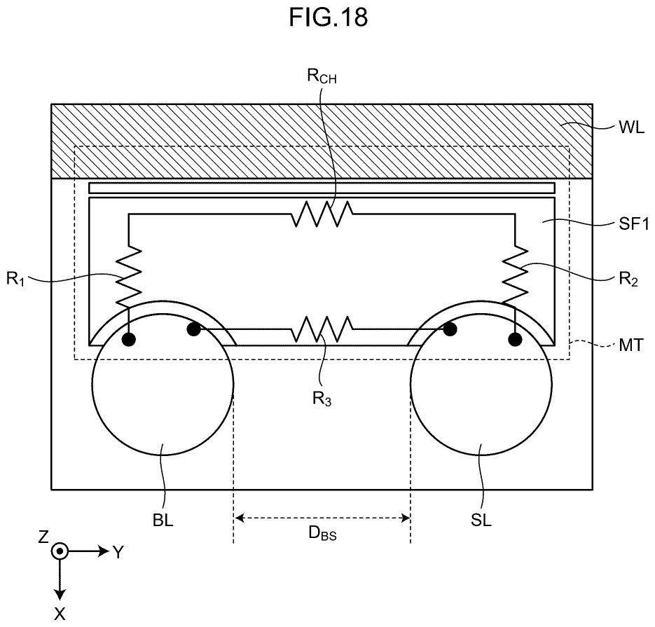

The configuration illustrated in FIG. 17 is illustrated in an equivalent circuit as illustrated in FIG. 18. FIG. 18 is a plan view illustrating an equivalent circuit of the memory cell MT.

As illustrated in FIGS. 17 and 18, when the memory cell MT is turned on, the semiconductor film SF1 has a −X side portion that functions as resistance RCH corresponding to the channel, a portion corresponding to the region RG1 that functions as resistance R1 between the channel and the conductive film BL, and a portion corresponding to the region RG2 that functions as resistance R2 between the channel and the conductive film SL.

Here, since each of the region RG1 and the region RG2 contains the first conductive type impurity at the concentration C1 and the concentration C1 is higher than the concentration C2, the pieces of resistance R1 and R2 can be decreased. As illustrated in FIG. 19, a cell current Ion when the memory cell MT is the on state can be secured. FIG. 19 is a plan view illustrating the electron density distribution when the memory cell MT is in the on state, and illustrates that the shading difference is small and the electron density is high in the −Y side portion of the region RG1 and the +Y side portion of the region RG2. That is, it is illustrated that the cell current Ion can be secured in the −Y side portion of the region RG1 and the +Y side portion of the region RG2.

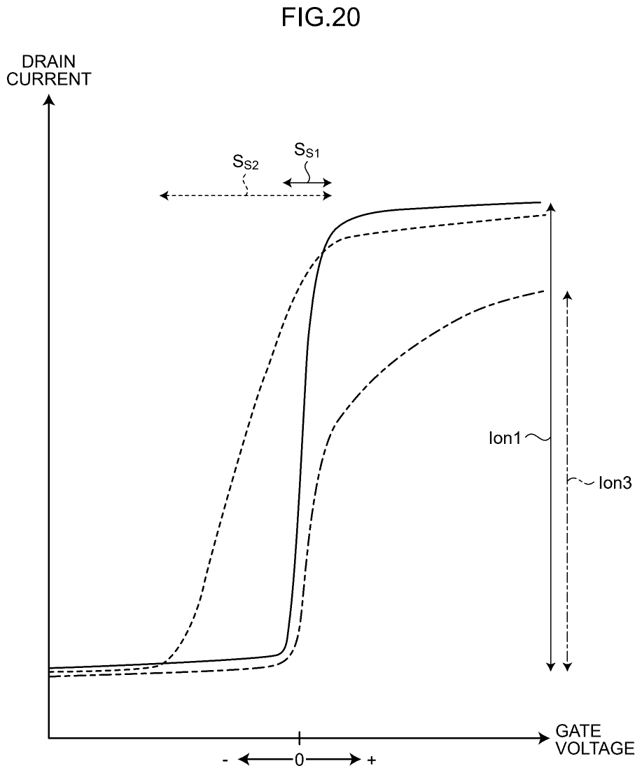

For example, FIG. 20 is a diagram illustrating the on/off characteristics of the memory cell MT, in which the vertical axis indicates the drain current of the memory cell MT and the horizontal axis indicates the gate voltage. FIG. 20 illustrates a case where the memory cell MT is turned on when the gate voltage changes from a negative value to a positive value. In FIG. 20, the third embodiment is illustrated by the solid line, the case where the regions RG1 and RG2 do not contain impurities is illustrated by the dashed line, and the case where the region RG3 does not contain impurities is illustrated by the dotted line.

When the regions RG1 and RG2 do not contain impurities, the resistance R1 between the channel and the conductive film BL and the resistance R2 between the channel and the conductive film SL tend to be high, and as illustrated by the dashed line in FIG. 20, a cell current Ion3 in the on state is relatively small.

On the other hand, since each of the region RG1 and the region RG2 contains the first conductive type impurity at the concentration C1 and the concentration C1 is higher than the concentration C2, the pieces of resistance R1 and R2 can be decreased. Then, a relatively large cell current Ion1 in the on state can be secured as illustrated by the solid line in FIG. 20.

Further, when the memory cell MT is turned on, the portion of the semiconductor film SF1 corresponding to the region RG3 functions as resistance R3 between the conductive film BL and the conductive film SL.

Here, since the region RG3 contains the second conductive type impurity at the concentration C2 and the concentration C2 is lower than the concentration C1, the resistance R3 can be increased. Accordingly, as illustrated in FIG. 19, the leakage between the conductive film BL and the conductive film SL in the on state of the memory cell MT can be reduced. In FIG. 19, it is illustrated that the difference in shading is large in the portion between the conductive film BL and the conductive film SL, and the electron density is low. That is, the leakage between the conductive film BL and the conductive film SL can be reduced.

For example, when the region RG3 does not contain impurities, leakage is likely to occur between the conductive film BL and the conductive film SL, and as illustrated by the dotted line in FIG. 20, a subthreshold swing value Ss: when the memory cell MT is in the on state is relatively large.

On the other hand, since the region RG3 contains the second conductive type impurity at the concentration C2 and the concentration C2 is lower than the concentration C1, the resistance R3 can be increased, and the leakage between the conductive film BL and the conductive film SL can be suppressed. Accordingly, as illustrated by the solid line in FIG. 20, a subthreshold swing value S_{S1} of the memory cell MT in the on state can be kept relatively small.

Accordingly, even when the conductive film SL and the conductive film BL are brought closer to each other in the semiconductor film SF1, deterioration of the on/off characteristics of the memory cell MT can be suppressed and an on-current can be secured.

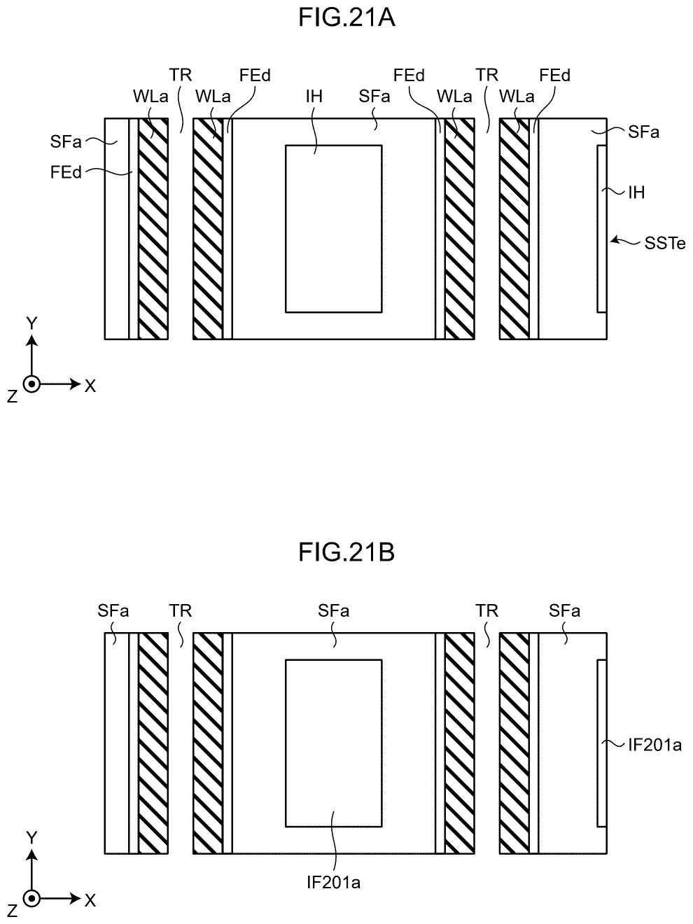

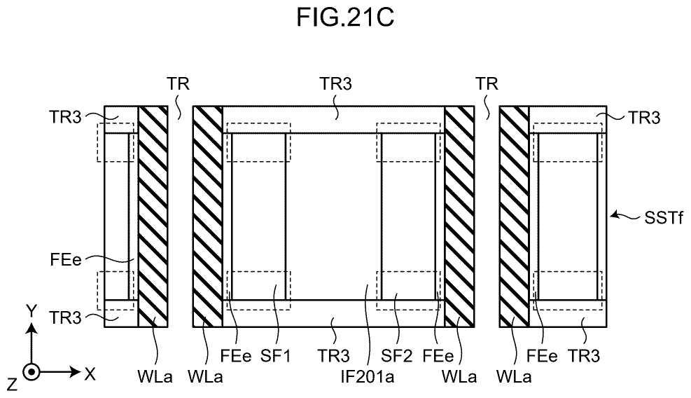

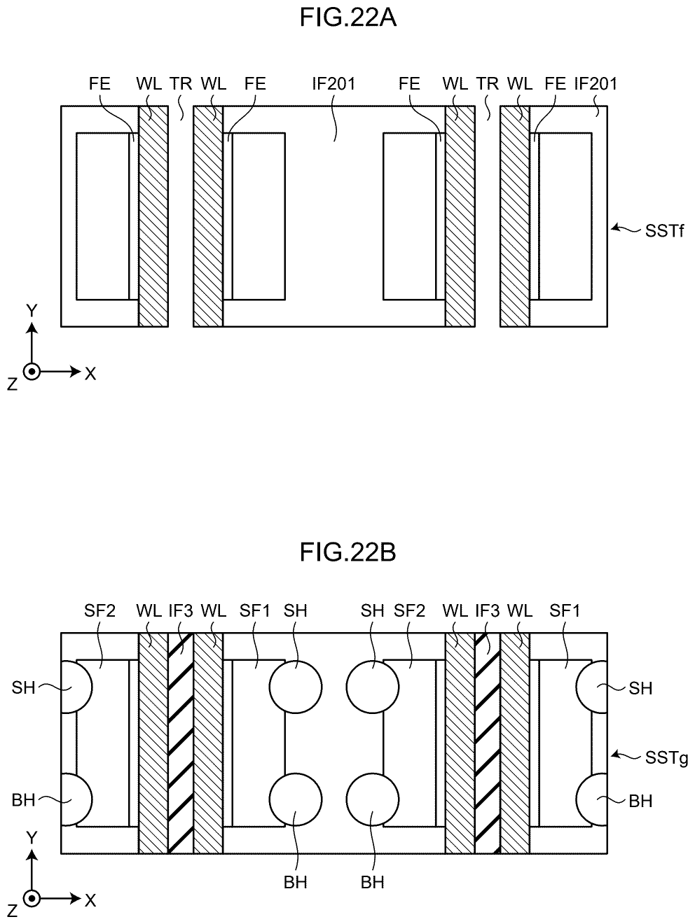

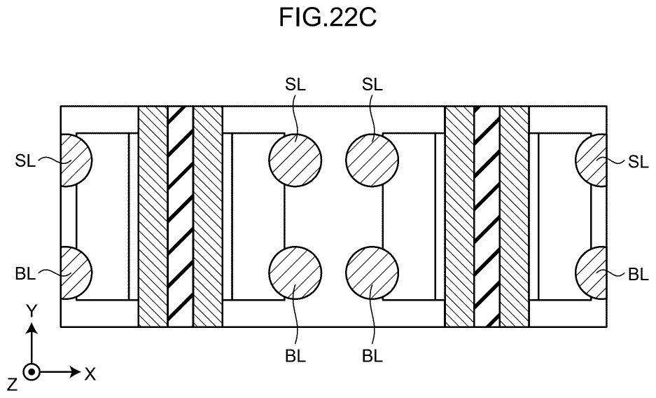

Next, a method of manufacturing the semiconductor memory device 201 is different from that of the first embodiment in the following points as illustrated in FIGS. 21A to 21C and FIGS. 22A to 22C. FIGS. 21A to 22C are plan views illustrating the method of manufacturing the semiconductor memory device 201. FIGS. 21A to 22C each correspond to an XY cross section taken along line D-D in FIG. 7E.

In the step illustrated in FIG. 7A, the semiconductor film SFa can be formed of a material mainly composed of a semiconductor (for example, silicon) containing a second conductive type impurity at the concentration C2. The second conductive type impurity may be a P-type impurity such as boron or aluminum. The concentration C2 may be equal to or larger than 5.0×10¹⁷ cm⁻³ and smaller than 1.0×10¹⁸ cm⁻³. Otherwise, the step illustrated in FIG. 7A is performed as in the first embodiment.

After the step illustrated in FIG. 7B is performed as in the first embodiment, a sacrificial film FEc is deposited on the side surface and the bottom surface of the trench TR instead of the insulating film FEa in the step illustrated in FIG. 7C. The sacrificial film FEc can be formed of any insulator capable of ensuring an etching selectivity with respect to each of the sacrificial film WLa and the semiconductor film SFa. The sacrificial film FEc may be formed of a semiconductor oxynitride such as silicon oxynitride.

A resist pattern having openings corresponding to the positions for forming the slit IF3 (see FIG. 1) is formed on the uppermost insulating layer IF2 of each stacked body SSTb. Using the resist pattern as a mask, anisotropic etching such as reactive ion etching (RIE) is performed. Accordingly, the sacrificial film FEc in the trench TR is removed while remaining the portion buried in the recess TRa of the sacrificial film FEc.

An insulating film recess process is performed to etch and recess the side surface of the sacrificial film FEc exposed by the trench TR. The recess TRb is formed on the inner surface of the trench TR by the insulating film recess process. The recess TRb is formed at the Z position of a sacrificial film FEd in the stacked body SSTb in a direction away from the X-direction center plane CP of the trench TR with respect to the inner surface of the trench TR. For example, the inner surface of the trench TR is wet-etched using an etchant having a high etching selectivity of the sacrificial film FEd to the insulating layer IF2. Alternatively, the inner surface of the trench TR is dry-etched under the condition of isotropic etching using a processing gas having a high etching selectivity of the insulating film FEb with respect to the insulating layer IF2. Accordingly, the recess TRb is formed on the inner surface of the trench TR by etching and recessing the side surface of the sacrificial film FEd exposed by the trench TR. The recess width (recess amount) of the recess TRb with respect to the inner surface of the trench TR can be adjusted by the etching time. The width of the recess TRb in the Z direction is approximately equal to the film thickness of the semiconductor film SFb.

In the step illustrated in FIG. 7D, the sacrificial film WLa is buried in the trench TR and the recess TRb instead of the barrier metal BM2, the barrier metal BM1, and the conductive film WL. The sacrificial film WLa may be formed of any insulator capable of ensuring an etching selectivity with respect to each of the sacrificial film FEc and the insulating layer IF2. The sacrificial film WLa may be formed of a semiconductor nitride such as silicon nitride.

A resist pattern having openings corresponding to the positions for forming the slit IF3 (see FIG. 1) is formed on the uppermost insulating layer IF2 of each stacked body SSTb. Using the resist pattern as a mask, anisotropic etching such as reactive ion etching (RIE) is performed. Accordingly, the sacrificial film WLa in the trench TR is removed while remaining the portion buried in the recess TRb of the sacrificial film WLa.

Thereafter, the step illustrated in FIG. 21A is performed.

In the step illustrated in FIG. 21A, a resist pattern having openings corresponding to the positions for forming the portions (see FIG. 15) between the semiconductor film SF1 and the semiconductor film SF2 in the insulating film IF201 is formed on the uppermost insulating layer IF2 of each stacked body SSTb. Using the resist pattern as a mask, anisotropic etching such as reactive ion etching (RIE) is performed. Accordingly, a hole IH is formed between the XY-direction center and the +Y side end of the semiconductor film SFa to penetrate the stacked body SSTe in the Z direction and reach the semiconductor film SFa on the −Z side. At this time, the hole IH is formed so that the portions of the semiconductor film SFa connected in the Y direction remain on both sides in the X direction.

In the step illustrated in FIG. 21B, an insulating film IF201a is buried in the hole IH. For example, the insulating film IF201a can be formed of an insulating material such as silicon oxide. Accordingly, the insulating film IF201a is formed to penetrate the semiconductor film SFa, extend in the Z direction, and reach the semiconductor film SFa closest to the −Z side.

In the step illustrated in FIG. 21C, a resist pattern having openings corresponding to the positions for forming both end portions (see FIG. 15) of the insulating film IF201 in the Y direction is formed on the uppermost insulating layer IF2 of each stacked body SSTe. Using the resist pattern as a mask, anisotropic etching such as reactive ion etching (RIE) is performed. Accordingly, a trench TR3 is formed at a position, dividing the semiconductor film SFa and the sacrificial films FEd on both sides in the X direction in the Y direction, to extend in the X direction, penetrate a stacked body SSTf in the Z direction, and reach the interlayer insulating film 81. At this time, the trench TR3 is formed so that the portions of the sacrificial film WLa connected in the Y direction remain on both sides in the X direction. Accordingly, the semiconductor film SFb is divided into multiple semiconductor films SF1 and SF2 arranged in the X direction with the insulating film IF201a interposed therebetween, and the sacrificial film FEd is divided into multiple sacrificial films FEe arranged in the Y direction with the trench TR3 interposed therebetween.

A resist pattern having openings corresponding to the positions for forming the region RG1 and the region RG2 (see FIG. 17) surrounded by the dotted line is formed on the uppermost insulating layer IF2 of each stacked body SSTe. Using the resist pattern as a mask, impurities are doped by ion implantation methods or the like. Accordingly, the region surrounded by the dotted line is doped with a first conductive type impurity at a concentration C1. The first conductive type impurity may be an N-type impurity such as phosphorus or arsenic. The concentration C1 may be equal to or larger than 1.0×10¹⁸ cm⁻³.

In the step illustrated in FIG. 22A, isotropic etching such as wet etching is performed through the trench TR3 to remove the sacrificial film FEd. The insulating film FE is buried in the gap formed by removing the sacrificial film FEd. The insulating film FE can be formed of a material mainly composed of a ferroelectric material. The insulating film FE can be formed of an amorphous material.

For example, the insulating film FE can be formed of a material mainly composed of hafnium oxide (HfO). The insulating film FEf may be formed of a material further containing at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The stacked body SSTf is subjected to heat treatment. Accordingly, the insulating film FE in an amorphous state is crystallized and becomes polycrystalline. At the same time, the crystallinity of the semiconductor films SF1 and SF2 is improved.

The insulating film IF201 is buried in the trench TR3. The insulating film IF201 can be formed of an insulating material such as silicon oxide.

Isotropic etching such as wet etching is performed through the trench TR to remove the sacrificial film WLa. The conductive film WL is buried in the gap formed by removing the sacrificial film WLa. For example, the conductive film WL can be formed of a material mainly composed of a metal such as tungsten (W).

In the step illustrated in FIG. 22B, the slit IF3 is buried in the trench TR. The slit IF3 can be formed of an insulator such as silicon oxide.

A resist pattern having openings corresponding to the positions for forming the conductive films SL and BL (see FIG. 15) is formed on the uppermost insulating layer IF2 of each stacked body SSTf. Using the resist pattern as a mask, anisotropic etching such as reactive ion etching (RIE) is performed. Accordingly, the hole SH is formed on the +X side and +Y side ends of the semiconductor film SF1 or the −X side and +Y side ends of the semiconductor film SF2 to penetrate a stacked body SSTg in the Z direction and reach the semiconductor film SF1 or the semiconductor film SF2 closest to the −Z side, and the hole BH is formed on the +X side and +Y side ends of the semiconductor film SF1 or the −X side and +Y side ends of the semiconductor film SF2 to penetrate the stacked body SSTg in the Z direction and reach the semiconductor film SF1 or the semiconductor film SF2 closest to the −Z side. At this time, the hole SH is formed so that the portions of the semiconductor film SF1 or the semiconductor film SF2 connected in the Y direction remain on the −X side or the +X side. The hole BH is formed so that the portions of the semiconductor film SF1 or the semiconductor film SF2 connected in the Y direction remain on the −X side or the +X side.

In the step illustrated in FIG. 22C, the conductive film SL is buried in the hole SH, and the conductive film BL is buried in the hole BH. For example, the conductive film SL can be formed of a material mainly composed of a metal such as tungsten (W). For example, the conductive film BL can be formed of a material mainly composed of a metal such as tungsten (W). Accordingly, the conductive film SL is formed to penetrate the semiconductor film SF1 or the semiconductor film SF2, extend in the Z direction, and reach the semiconductor film SF1 or the semiconductor film SF2 closest to the −Z side, and the conductive film BL is formed to penetrate the semiconductor film SF1 or the semiconductor film SF2, extend in the Z direction, and reach the semiconductor film SF1 or the semiconductor film SF2 closest to the −Z side.

As described above, in the third embodiment, in each memory cell MT of the memory cell array 202, each of the region RG1 and the region RG2 on both end sides of the semiconductor film SF1 or SR2 in the Y direction contains the first conductive type impurity at the concentration C1. Accordingly, the equivalent resistance of the regions RG1 and RG2 can be decreased, and a relatively large on-state cell current Ion1 can be secured. Further, in each memory cell MT, the region RG3 at the center in the Y direction contains the second conductive type impurity at the concentration C2. The concentration C2 is lower than the concentration C1. The region RG3 is interposed between the conductive film SL and the conductive film BL. Accordingly, the equivalent resistance of the region RG3 can be increased, and the leakage between the conductive film BL and the conductive film SL can be reduced. Accordingly, in the semiconductor film SF1, even when the conductive film SL and the conductive film BL are brought close to each other, the deterioration of the on/off characteristics of the memory cell MT can be suppressed and the on-current can be secured. As a result, in the semiconductor memory device 201, the cell size of each memory cell MT can be decreased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first conductive film which extends in a first direction;
a second conductive film which is separated from the first conductive film in a second direction intersecting the first direction and extends in the first direction;
a first semiconductor film which is disposed between the first conductive film and the second conductive film and extends in the first direction and the second direction;
a first insulating film which is disposed between the first conductive film and the first semiconductor film and extends in the first direction;
a second insulating film which is disposed between the second conductive film and the first semiconductor film and extends in the first direction;
a third conductive film which extends in a third direction intersecting the first direction and the second direction within the first semiconductor film;
a fourth conductive film which is separated from the third conductive film in the first direction and extends in the third direction within the first semiconductor film; and
a fifth conductive film which extends in the third direction within the first semiconductor film between the third conductive film and the fourth conductive film and to which a reference potential is applied,
wherein a first memory cell is provided at a position in which the first semiconductor film faces the first conductive film with the first insulating film interposed therebetween, and
a second memory cell is provided at a position in which the first semiconductor film faces the second conductive film with the second insulating film interposed therebetween.

2. The semiconductor memory device according to claim 1,
wherein the third conductive film, the fourth conductive film, and the fifth conductive film are arranged along the first direction between the first memory cell and the second memory cell.

3. The semiconductor memory device according to claim 2,
wherein the third conductive film, the fourth conductive film, and the fifth conductive film are separated from each other in the first direction.

4. The semiconductor memory device according to claim 1,
wherein each of the first insulating film and the second insulating film contains a ferroelectric material.

5. The semiconductor memory device according to claim 1, further comprising:
a substrate,
wherein the fifth conductive film extends in the third direction and reaches the substrate, and
each of the third conductive film and the fourth conductive film does not reach the substrate.

6. The semiconductor memory device according to claim 1,
wherein a first fixed potential is applied to the fifth conductive film when data is written to at least one of the first memory cell and the second memory cell, and a second fixed potential is applied thereto when data is read from at least one of the first memory cell and the second memory cell.

7. The semiconductor memory device according to claim 1, further comprising:
a sixth conductive film which is separated from the first conductive film in the third direction and extends in the first direction;
a seventh conductive film which is separated from the sixth conductive film in the second direction and extends in the first direction;
a second semiconductor film which is disposed between the sixth conductive film and the seventh conductive film and extends in the first direction and the second direction;
a third insulating film which is disposed between the sixth conductive film and the second semiconductor film and extends in the first direction; and
a fourth insulating film which is disposed between the seventh conductive film and the second semiconductor film and extends in the first direction,
wherein each of the third conductive film, the fourth conductive film, and the fifth conductive film further extends in the third direction within the second semiconductor film,
a third memory cell is provided at a position in which the second semiconductor film faces the sixth conductive film with the third insulating film interposed therebetween, and
a fourth memory cell is provided at a position in which the second semiconductor film faces the seventh conductive film with the fourth insulating film interposed therebetween.

8. The semiconductor memory device according to claim 7,
wherein the third conductive film, the fourth conductive film, and the fifth conductive film are arranged in the first direction between the first memory cell and the second memory cell and are arranged in the first direction between the third memory cell and the fourth memory cell.

9. The semiconductor memory device according to claim 8,
wherein the third conductive film, the fourth conductive film, and the fifth conductive film are separated from each other in the first direction.

10. A semiconductor memory device comprising:
a first conductive film which extends in a first direction;
a second conductive film which is separated from the first conductive film in a second direction intersecting the first direction and extends in the first direction;
a first semiconductor film which is disposed between the first conductive film and the second conductive film and extends in the first direction;
a second semiconductor film which is disposed between the first semiconductor film and the second conductive film and extends in the first direction;
a first insulating film which is disposed between the first conductive film and the first semiconductor film and extends in the first direction;
a second insulating film which is disposed between the second conductive film and the second semiconductor film and extends in the first direction;
a third conductive film which extends in a third direction intersecting the first direction and the second direction between the first semiconductor film and the second semiconductor film and is connected to each of the first semiconductor film and the second semiconductor film; and
a fourth conductive film which is separated from the third conductive film in the first direction with an air gap interposed therebetween, extends in the third direction between the first semiconductor film and the second semiconductor film, and is connected to each of the first semiconductor film and the second semiconductor film,
wherein a first memory cell is provided at a position in which the first semiconductor film faces the first conductive film with the first insulating film interposed therebetween, and
a second memory cell is provided at a position in which the second semiconductor film faces the second conductive film with the second insulating film interposed therebetween.

11. The semiconductor memory device according to claim 10,
wherein each of the first insulating film and the second insulating film contains a ferroelectric material.

12. The semiconductor memory device according to claim 10,
wherein a difference between the crystal orientation of the first semiconductor film and the crystal orientation of the second semiconductor film is 5° or less.

13. The semiconductor memory device according to claim 10,
wherein a width of the air gap in the second direction is smaller than a width of the third conductive film in the second direction and is smaller than a width of the fourth conductive film in the second direction.

14. The semiconductor memory device according to claim 10, further comprising:
a fifth conductive film which is separated from the first conductive film in the third direction and extends in the first direction;
a sixth conductive film which is separated from the fifth conductive film in the second direction and extends in the first direction;
a third semiconductor film which is disposed between the fifth conductive film and the sixth conductive film and extends in the first direction;
a fourth semiconductor film which is disposed between the third semiconductor film and the sixth conductive film and extends in the first direction;
a third insulating film which is disposed between the fifth conductive film and the third semiconductor film and extends in the first direction; and
a fourth insulating film which is disposed between the sixth conductive film and the fourth semiconductor film and extends in the first direction,
wherein the third conductive film further extends in the third direction between the third semiconductor film and the fourth semiconductor film and is connected to each of the third semiconductor film and the fourth semiconductor film,
the fourth conductive film is separated from the third conductive film in the first direction with the air gap interposed therebetween, further extends in the third direction between the third semiconductor film and the fourth semiconductor film, and is connected to each of the third semiconductor film and the fourth semiconductor film,
a third memory cell is provided at a position in which the third semiconductor film faces the fifth conductive film with the third insulating film interposed therebetween, and
a fourth memory cell is provided at a position in which the fourth semiconductor film faces the sixth conductive film with the fourth insulating film interposed therebetween.

15. The semiconductor memory device according to claim 14,
wherein the air gap extends in the third direction between the first memory cell and the second memory cell, and extends in the third direction between the third memory cell and the fourth memory cell.

16. A semiconductor memory device comprising:
a first conductive film which extends in a first direction;
a first semiconductor film which extends in the first direction and a second direction intersecting the first direction;
a first insulating film which is disposed between the first conductive film and the first semiconductor film and extends in the first direction;
a third conductive film which extends in a third direction intersecting the first direction and the second direction and is connected to the first semiconductor film; and
a fourth conductive film which is separated from the third conductive film in the first direction, extends in the third direction, and is connected to the first semiconductor film,
wherein a first memory cell is provided at a position in which the first semiconductor film faces the first conductive film with the first insulating film interposed therebetween,
the first semiconductor film includes
a first region which is disposed between the first conductive film and the third conductive film,
a second region which is disposed between the first conductive film and the fourth conductive film, and
a third region which is disposed between the first region and the second region, and
each of the first region and the second region contains a first conductive type impurity.

17. The semiconductor memory device according to claim 16,
wherein the third region contains a second conductive type impurity.

18. The semiconductor memory device according to claim 17,
wherein each of the first region and the second region contains the first conductive type impurity at a concentration equal to or higher than a first concentration, and
the third region contains the second conductive type impurity at a concentration lower than the first concentration.

19. The semiconductor memory device according to claim 18,
wherein the third region contains the second conductive type impurity at a concentration equal to or higher than a second concentration and lower than the first concentration.

20. The semiconductor memory device according to claim 16,
wherein the first insulating film contains a ferroelectric material.
